(19) United States
(12) Patent Application Publication
(10) Pub. No.: US 2025/0393394 A1
(43) Pub. Date: Dec. 25, 2025

(54) Array Substrate, Display Panel and Display Apparatus

(71) Applicant: BOE TECHNOLOGY GROUP CO., LTD., Chaoyang District, Beijing (CN)

(72) Inventors: Dongni Liu, Beijing (CN); Zhen Zhang, Beijing (CN); Peirou Li, Beijing (CN); Minghua Xuan, Beijing (CN); Zhenyu Zhang, Beijing (CN); Shunhang Zhang, Beijing (CN); Yunsik Im, Beijing (CN); Lianfu Yu, Beijing (CN)

(21) Appl. No.: 18/857,599

(22) PCT Filed: Jan. 3, 2024
(86) PCT No.: PCT/CN2024/070403

§ 371 Date: Oct. 17, 2024

(51) Int. Cl. H10K 59/121

(52) U.S. Cl. CPC H10K 59/1213

(57) ABSTRACT

An array substrate includes pixel driving circuits arranged in rows and columns. Each pixel driving circuit includes transistors. The transistors include at least a sensing transistor. The array substrate includes: a base substrate, a transistor distribution layer, and a first source-drain metal layer. The transistor distribution layer is disposed on a side of the base substrate. The transistor distribution layer is provided therein with an active layer pattern of the sensing transistor and a gate pattern of the sensing transistor. The active layer pattern of the sensing transistor is farther away from the base substrate than the gate pattern of the sensing transistor. The first source-drain metal layer is disposed on a side of the transistor distribution layer away from the base substrate. The first source-drain metal layer includes a first anode transfer pattern. The first anode transfer pattern is connected to the active layer pattern of the sensing transistor.

### CROSS-REFERENCE TO RELATED APPLICATION

This application is the United States national phase of International Patent Application No. PCT/CN2024/070403, filed Jan. 3, 2024, the disclosure of which is hereby incorporated by reference in its entirety.

### BACKGROUND OF THE INVENTION

### FIELD OF THE INVENTION

The present disclosure relates to the field of display technologies, in particular to an array substrate, a display panel and a display apparatus.

### DESCRIPTION OF RELATED ART

At present, organic light-emitting diode (OLED) display apparatuses have been widely used due to their characteristics such as self-luminescence, quick response, wide viewing angle, being capable of being manufactured on flexible substrates. The OLED display apparatus includes a plurality of sub-pixels, each sub-pixel includes a pixel driving circuit and a light-emitting device, and the pixel driving circuit drives the light-emitting device to emit light, thereby achieving the display.

### SUMMARY OF THE INVENTION

In an aspect, an array substrate is provided. The array substrate includes a plurality of pixel driving circuits arranged in a plurality of rows and a plurality of columns, each of the plurality of pixel driving circuits includes a plurality of transistors, and the plurality of transistors include at least a sensing transistor. The array substrate includes a base substrate, a transistor distribution layer and a first source-drain metal layer. The transistor distribution layer is disposed on a side of the base substrate, the transistor distribution layer is provided therein with an active layer pattern of the sensing transistor and a gate pattern of the sensing transistor, and the active layer pattern of the sensing transistor is farther away from the base substrate than the gate pattern of the sensing transistor. The first source-drain metal layer is disposed on a side of the transistor distribution layer away from the base substrate, the first source-drain metal layer includes a first anode transfer pattern, and the first anode transfer pattern is connected to the active layer pattern of the sensing transistor.

In some embodiments, the active layer pattern of the sensing transistor is connected to a sensing line transfer pattern, and the sensing line transfer pattern is located in the first source-drain metal layer. The array substrate further includes a second source-drain metal layer. The second source-drain metal layer includes a sensing line, and the active layer pattern of the sensing transistor is connected to the sensing line through the sensing line transfer pattern.

In some embodiments, the transistor distribution layer includes a plurality of transistor distribution sub-layers, and each of the transistor distribution sub-layers includes an active film layer and a gate film layer that are stacked; the active film layer includes an active layer pattern of a transistor, and the gate film layer includes a gate pattern of a transistor; active film layers of the plurality of transistor distribution sub-layers are stacked; an active film layer of at least one transistor distribution sub-layer is a polysilicon active film layer, and an active film layer of at least one transistor distribution sub-layer is an oxide active film layer; the plurality of transistors further include a writing transistor and a driving transistor; at least one of active layer patterns of the sensing transistor, the writing transistor and the driving transistor is located in the polysilicon active film layer; and at least one of the active layer patterns is located in the oxide active film layer.

In some embodiments, the plurality of transistor distribution sub-layers include a first transistor distribution sub-layer and a second transistor distribution sub-layer; an active film layer of the first transistor distribution sub-layer is closer to the base substrate than an active film layer of the second transistor distribution sub-layer; a gate film layer of the first transistor distribution sub-layer and a gate film layer of the second transistor distribution sub-layer are located between the active film layer of the first transistor distribution sub-layer and the active film layer of the second transistor distribution sub-layer; the gate film layer of the first transistor distribution sub-layer and the gate film layer of the second transistor distribution sub-layer are located in a same layer; the writing transistor and the driving transistor are located in the first transistor distribution sub-layer; and the sensing transistor is located in the second transistor distribution sub-layer.

In some embodiments, the array substrate further includes a third source-drain metal layer. The third source-drain metal layer includes a data signal line. An active layer pattern of the writing transistor is connected to the data signal line through a data signal transfer pattern; the data signal transfer pattern is located in a first transfer gate film layer; the first transfer gate film layer is located between active film layers of adjacent transistor distribution sub-layers, or the first transfer gate film layer and the first source-drain metal layer are located in a same layer; one of the second source-drain metal layer and the third source-drain metal layer is disposed on a side of the transistor distribution layer close to the base substrate, and another of the second source-drain metal layer and the third source-drain metal layer is disposed on a side of the first source-drain metal layer away from the base substrate.

In some embodiments, in a case where the second source-drain metal layer is disposed on the side of the first source-drain metal layer away from the base substrate, an orthogonal projection of the sensing line on the base substrate covers an orthogonal projection of a channel region of an active layer pattern of the sensing transistor on the base substrate.

In some embodiments, an active layer pattern of the writing transistor is connected to a gate pattern of the driving transistor through a first transfer pattern; and the first transfer pattern is located in the first source-drain metal layer.

In some embodiments, an active layer pattern of the driving transistor is connected to a first voltage signal line through via holes; and the first voltage signal line is located in the first source-drain metal layer.

In some embodiments, the array substrate further includes a light-shielding layer. The light-shielding layer is disposed on a side of the transistor distribution layer close to the base substrate. At least one of the plurality of transistors is a dual-gate transistor, the dual-gate transistor is disposed in a transistor distribution sub-layer closest to the base substrate, and a gate film layer of the transistor distribution sub-layer closest to the base substrate includes a top-gate pattern of the dual-gate transistor; and the light-shielding layer includes a bottom-gate pattern of the dual-gate transistor.

In some embodiments, the light-shielding layer and the second source-drain metal layer are located in a same layer.

In some embodiments, the array substrate includes a plurality of sub-pixel regions arranged in a plurality of rows and a plurality of columns, and patterns of at least two film layers in every two adjacent sub-pixel regions arranged in a column direction are symmetrically arranged.

In some embodiments, the array substrate includes a plurality of sub-pixel regions arranged in a plurality of rows and a plurality of columns, and patterns of at least two film layers in every two adjacent sub-pixel regions arranged in a row direction are symmetrically arranged.

In some embodiments, a size of a sub-pixel region in the column direction is greater than a size of the sub-pixel region in a row direction.

In some embodiments, a ratio of the size of the sub-pixel region in the row direction to the size of the sub-pixel region in the column direction is 1:3 or 1:2.

In some embodiments, the array substrate further includes a planarization layer. The planarization layer is disposed on a side of the first source-drain metal layer away from the base substrate. The first anode transfer pattern is connected to an anode through a via hole penetrating the planarization layer.

In some embodiments, the array substrate further includes a planarization layer and a fifth source-drain metal layer. The planarization layer is disposed on a side of the first source-drain metal layer away from the base substrate. The fifth source-drain metal layer is disposed between the first source-drain metal layer and the planarization layer. The fifth source-drain metal layer includes a second anode transfer pattern; and the first anode transfer pattern is connected to an anode through the second anode transfer pattern.

In another aspect, a display panel is provided. The display panel includes the array substrate as described in any one of the above embodiments and an anode layer. The anode layer is disposed on a side of the array substrate. The anode layer includes a plurality of anodes, and the anodes are connected to the array substrate.

In yet another aspect, a display apparatus is provided. The display apparatus includes the display panel as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is an equivalent circuit diagram of a pixel driving circuit, in accordance with some embodiments of the present disclosure;

FIG. 4 is a structural diagram of another display panel, in accordance with some embodiments of the present disclosure;

FIG. 5 is a structural diagram of a display panel, in accordance with some embodiments;

FIG. 6 is a structural diagram of a display panel, in accordance with some embodiments of the present disclosure;

FIG. 7 is a structural diagram of another display panel, in accordance with some embodiments of the present disclosure;

FIG. 8 is a structural diagram of yet another display panel, in accordance with some embodiments of the present disclosure;

FIG. 9 is a structural diagram of yet another display panel, in accordance with some embodiments of the present disclosure;

FIG. 10 is a structural diagram of yet another display panel, in accordance with some embodiments of the present disclosure;

FIG. 11A is a structural diagram of stacked film layers in a plurality of sub-pixel regions of an array substrate, in accordance with some embodiments of the present disclosure;

FIG. 11B is an enlarged view of the region E in FIG. 11A;

FIG. 11C is an enlarged view of the region F in FIG. 11B;

FIGS. 12A to 12O are structural diagrams of film layers, in accordance with some embodiments of the present disclosure;

FIG. 13A is a structural diagram of stacked film layers in a plurality of sub-pixel regions of an array substrate, in accordance with some embodiments of the present disclosure;

FIG. 13B is an enlarged view of the region M in FIG. 13A;

FIG. 13C is an enlarged view of the region N in FIG. 13B;

FIGS. 14A to 14O are structural diagrams of film layers, in accordance with some embodiments of the present disclosure;

FIG. 15 is a structural diagram of a sub-pixel region, in accordance with some embodiments of the present disclosure; and

FIG. 16 is a structural diagram of another sub-pixel region, in accordance with some embodiments of the present disclosure.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, terms such as “first” and “second” are only used for descriptive purposes, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of regions in a device, and are not intended to limit the scope of the exemplary embodiments.

Some embodiments of the present disclosure provide a display apparatus. The display apparatus is an electronic device having a function of displaying images (including an image in stationary or an image in motion (which may be a video)). For example, the display apparatus may be any one of a display, a television, a billboard, a digital photo frame, a laser printer having a display function, a telephone, a mobile phone, a personal digital assistant (PDA), a digital camera, a portable camcorder, a view finder, a navigator, a large-area wall, a household appliance, an information inquiry device (e.g., a business inquiry device for a department of e-government, bank, hospital, electricity or the like), a monitor, an electronic picture screen, a virtual reality (VR) display device, an augmented reality (AR) display device, and a vehicle-mounted display, which will not be limited thereto.

For example, the display apparatus may be an electroluminescent display apparatus or a photoluminescent display apparatus. In a case where the display apparatus is the electroluminescent display apparatus, the electroluminescent display apparatus may be an organic light-emitting diode (OLED) display apparatus or a quantum dot light-emitting diode (QLED) display apparatus. In a case where the display apparatus is the photoluminescent display apparatus, the photoluminescent display apparatus may be a quantum dot photoluminescent display apparatus.

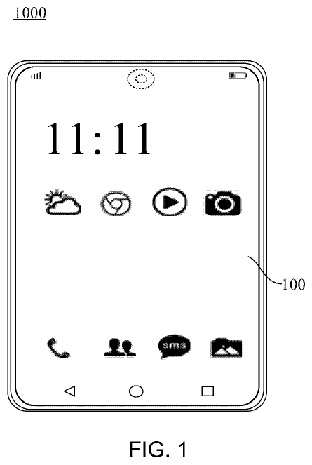

FIG. 1 is a structural diagram of a display apparatus provided in some embodiments of the present disclosure.

As shown in FIG. 1, the embodiments of the present disclosure are introduced by taking an example in which the display apparatus is a mobile phone. The display apparatus 1000 includes a display panel 100. The display panel 100 may be any one of an OLED display panel, a QLED display panel, a mini LED display panel, a micro LED display panel or the like.

The embodiments of the present disclosure are introduced by taking an example in which the display panel 100 is an OLED display panel, but the implementations of the present disclosure are not limited thereto.

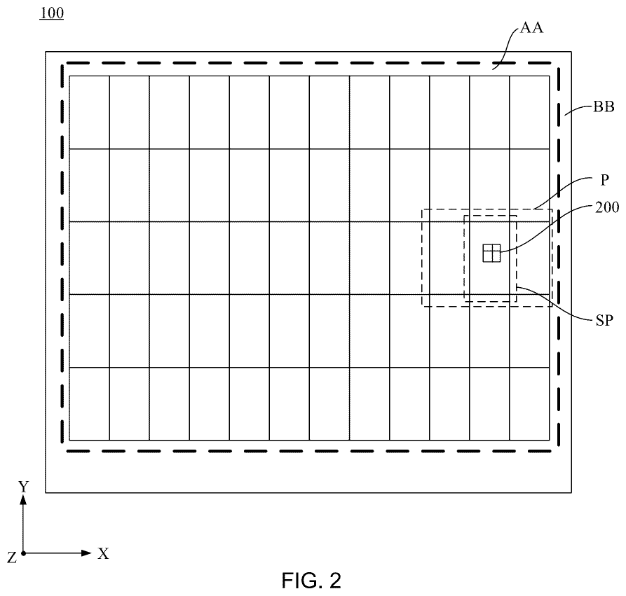

FIG. 2 is a structural diagram of a display panel provided in some embodiments of the present disclosure.

For convenience of the following description, an XYZ coordinate system is established. A first direction X and a second direction Y are both parallel to a plane where a display surface of the display panel 100 is located, and the first direction X and the second direction Y intersect. For example, the first direction X and the second direction Y are perpendicular to each other. A third direction Z is perpendicular to the plane where the display surface of the display panel 100 is located.

As shown in FIG. 2, the display panel 100 includes a display region AA and a peripheral region BB. The display region AA is a region of the display panel 100 for displaying images, and the peripheral region BB is a region of the display panel 100 other than the display region AA. The peripheral region BB may be located on at least one side (e.g., one side, or multiple sides) of the display region AA. For example, the peripheral region BB may be arranged around the display region AA.

The display region AA is provided therein with a plurality of pixels P and a plurality of signal lines. The plurality of pixels P are arranged in an array in the display region AA. The first direction X may be a row direction of the pixels P, and the second direction Y may be a column direction of the pixels P. Each pixel P includes a plurality of sub-pixels SP, and each sub-pixel SP may display a single color. For example, the pixel P includes a first sub-pixel, a second sub-pixel, and a third sub-pixel, which display red, green and blue, respectively.

The sub-pixel SP is the smallest unit in the display panel 100 for displaying images. Each sub-pixel SP includes a light-emitting device and a pixel driving circuit 200 for controlling the light-emitting device to emit light. That is, a sub-pixel SP corresponds to a pixel driving circuit 200. The pixel driving circuit 200 may be configured to write a data signal in response to a received scan signal, and drive the light-emitting device to emit light through an electrical signal. The light-emitting brightness of the light-emitting device may be positively correlated with a voltage value of a data signal line. By adjusting the brightness of different sub-pixels SP, multi-color display may be realized through color superposition.

The plurality of sub-pixels SP are arranged in the display region AA according to a specified rule. For example, the plurality of sub-pixels SP are arranged in a plurality of rows and a plurality of columns. Since each sub-pixel SP corresponds to a pixel driving circuit 200, pixel driving circuits 200 are also arranged in a plurality of rows and a plurality of columns.

The pixel driving circuit 200 includes a plurality of transistors and a capacitor. The pixel driving circuit may be a “3T1C”, “7T1C”, “8T1C”, or “9T1C” circuit, where “T” represents a thin film transistor, a number preceding “T” represents the number of thin film transistors, “C” represents a capacitor, and a number preceding “C” represents the number of capacitors. For example, “3T1C” refers to 3 transistors and 1 capacitor, and “7T1C” refers to 7 transistors and 1 capacitor.

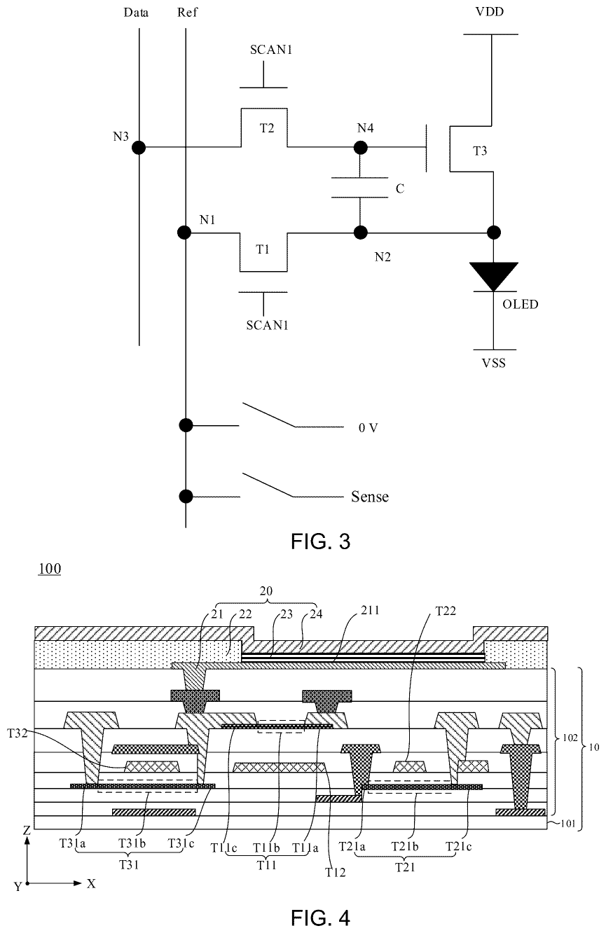

FIG. 3 is an equivalent circuit diagram of a pixel driving circuit provided in some embodiments of the present disclosure. The pixel driving circuit 200 will be introduced by taking the 3T1C type as an example.

As shown in FIG. 3, the pixel driving circuit 200 includes three transistors and one storage capacitor C, and the three transistors are a sensing transistor T1, a writing transistor T2 and a driving transistor T3.

For example, the sensing transistor T1, the writing transistor T2, and the driving transistor T3 may be P-type transistors, or may be N-type transistors. For example, the sensing transistor T1, the writing transistor T2, and the driving transistor T3 may include P-type transistor(s) and N-type transistor(s). As another example, the driving transistor T3, the writing transistor T2, and the sensing transistor T1 may all be N-type transistors or all be P-type transistors. The transistors in the pixel driving circuit 200 are of the same type, thereby simplifying the process flow, reducing the process difficulty of the array substrate 10, and improving the product yield.

The connection relationship between the sensing transistor T1, the writing transistor T2, the driving transistor T3, and the storage capacitor C in the pixel driving circuit and signal lines shown in FIG. 3 will be schematically described below.

Referring to FIG. 3, the signal lines electrically connected to the pixel driving circuit 200 include a sensing line Sense, a data signal line Data, a reset signal line Ref, a first scan line SCAN1, a second scan line SCAN2, a first voltage signal line VDD, and a second voltage signal line VSS.

A gate of the sensing transistor T1 is electrically connected to the first scan line SCAN1. A first electrode of the sensing transistor T1 is electrically connected to the reset signal line Ref through a first node N1, and the first electrode of the sensing transistor T1 is also electrically connected to the sensing line Sense through the first node N1. A second electrode of the sensing transistor T1 is connected to a first electrode plate of the storage capacitor C through a second node N2, and the second electrode of the sensing transistor T1 is also electrically connected to an anode of the light-emitting device OLED through the second node N2. The second electrode of the sensing transistor T1 is also electrically connected to a second electrode of the driving transistor T3 through the second node N2, and is used to reset an initial potential of the second electrode of the driving transistor T3, so as to sense a threshold voltage of the driving transistor T3 in real time. Therefore, the initial potential of the second electrode of the driving transistor T3 remains stable; and after the threshold voltage of the driving transistor T3 is sensed, the threshold voltage of the driving transistor T3 may be compensated. As a result, the light-emitting brightness of the light-emitting device OLED is not affected by the threshold voltage of the driving transistor T3, and the light-emitting brightness of the light-emitting device OLED remains stable.

A gate of the writing transistor T2 is electrically connected to the second scan line SCAN2, and a first electrode of the writing transistor T2 is electrically connected to the data signal line Data through a third node N3. The data signal line Data is used to transmit a data signal. A second electrode of the writing transistor T2 is connected to a second electrode plate of the storage capacitor C through a fourth node N4, and the second electrode of the writing transistor T2 is also connected to a gate of the driving transistor T3 through the fourth node N4. The writing transistor T2 writes a data voltage Vdata into the gate of the driving transistor T3, and the storage capacitor C stores the written data voltage Vdata, so that the driving transistor T3 remains on when the light-emitting device OLED emits light.

A first electrode of the driving transistor T3 is electrically connected to the first voltage signal line VDD, and the second electrode of the driving transistor T3 is electrically connected to the anode of the light-emitting device OLED. A cathode of the light-emitting device OLED is electrically connected to the second voltage signal line VSS. The first voltage signal line VDD is used to transmit a first voltage signal, e.g., a high voltage direct current signal, and the second voltage signal line VSS is used to transmit a second voltage signal, e.g., a low voltage direct current signal.

The first scan line SCAN1 is used to control on-off of the sensing transistor T1. When the threshold voltage of the driving transistor T3 is sensed, the writing transistor T2 is turned off and the sensing transistor T1 is turned on, so that the gate of the driving transistor T3 is in a floating state. When the driving transistor T3 is turned on and the potential of the first electrode of the driving transistor T3 is pulled up by the first voltage signal line VDD, due to the coupling effect of the storage capacitor C, a potential difference across the storage capacitor C will be kept stable, so that the potential of the gate of the driving transistor T3 will change with the change of the potential of the second electrode of the driving transistor T3. In this way, the potential difference Vgs between the gate and the second electrode of the driving transistor T3 can be kept stable, so that the light-emitting brightness of the light-emitting device OLED can be stabilized, and the mobility of the driving transistor T3 can be accurately sensed.

It will be noted that, in the present disclosure, a first electrode of a transistor is one of a source and a drain of the transistor, and a second electrode of the transistor is the other of the source and the drain of the transistor. Since the source and the drain of the transistor may be symmetrical in structure, there may be no difference in structure between the source and the drain of the transistor. That is, the first electrode and the second electrode of the transistor in the embodiments of the present disclosure may be the same in structure. For example, the transistor is a P-type transistor, the first electrode of the transistor is the source, and the second electrode of the transistor is the drain. For example, the transistor is an N-type transistor, the first electrode of the transistor is the source, and the second electrode of the transistor is the drain.

In the circuits provided in the embodiments of the present disclosure, nodes do not represent actual components, but represent junctions of relevant electrical connections in a circuit diagram. That is to say, these nodes are nodes equivalent to the junction points of the related electrical connections in the circuit diagram.

FIG. 4 is a structural diagram of another display panel according to some embodiments of the present disclosure.

Referring to FIG. 4, the display panel 100 includes an array substrate 10, a light-emitting device layer 20 and an encapsulation layer (not shown in the figure) that are stacked in sequence.

The light-emitting device layer 20 is disposed on a side of the array substrate 10. The light-emitting device layer 20 includes an anode layer 21, a pixel defining layer 22, a light-emitting layer 23, and a cathode layer 24. The anode layer 21 is disposed on the side of the array substrate 10. The anode layer 21 includes a plurality of anodes 211. The anodes 211 are connected to the array substrate 10. The specific connection method will be described in detail below. The light-emitting layer 23 includes a plurality of light-emitting portions, and each light-emitting portion overlaps with an anode 211. The pixel defining layer 22 is provided therein with a plurality of pixel openings 221, and each pixel opening 221 exposes a portion of an anode 211. The light-emitting portions in the light-emitting layer 23 are arranged in the pixel openings in one-to-one correspondence, so that an edge of the light-emitting portion may overlap an edge of the pixel opening. The cathode layer 24 is disposed on a side of the pixel defining layer 22 and the light-emitting layer 23 away from the array substrate 10.

The encapsulation layer is located on a side of the cathode layer 24 away from the array substrate 10. For example, the encapsulation layer may include a first inorganic layer, an organic encapsulation layer, and a second inorganic layer. The encapsulation layer is used to encapsulate the light-emitting device layer 20 to protect the light-emitting device layer 20.

The structure of the array substrate 10 will be described in detail below.

The pixel driving circuit 200 is arranged in the film layer structure of the array substrate 10. The structure of film layers included in the array substrate 10 and the arrangement of the transistors in the pixel driving circuit 200 will be introduced below.

Referring to FIG. 4, the array substrate 10 includes a base substrate 101 and a pixel circuit stacked layer 102. The pixel circuit stacked layer 102 includes a plurality of functional layers sequentially stacked on the base substrate 101, and an insulating layer located between adjacent functional layers. The insulating layer is used to prevent connection between adjacent functional layers. The insulating layer may be made of one or two inorganic insulating materials such as silicon oxide (SiOₓ), silicon nitride (SiNₓ), or silicon oxynitride (SiON). The functional layers may include an active film layer, a gate film layer and a source-drain metal layer. The active film layer, the gate film layer and the source-drain metal layer are used to form a plurality of pixel driving circuits in the display panel 100. The plurality of pixel driving circuits are formed in the display region AA of the display panel 100.

Active layer patterns of the plurality of transistors of the pixel driving circuit are located in the active film layer, and an active layer pattern of each transistor includes a first electrode region, a second electrode region and a channel region for connecting the first electrode region and the second electrode region. The first electrode region of the active layer pattern of the transistor corresponds to the first electrode of the transistor mentioned above, and the second electrode region of the active layer pattern of the transistor corresponds to the second electrode of the transistor mentioned above. For example, the active layer pattern T11 of the sensing transistor T1 includes a first electrode region T11a of the sensing transistor T1, a second electrode region T11c of the sensing transistor T1, and a channel region T11b of the sensing transistor T1 located between the first electrode region T11a of the sensing transistor T1 and the second electrode region T11c of the sensing transistor T1; the active layer pattern T21 of the writing transistor T2 includes a first electrode region T21a of the writing transistor T2, a second electrode region T21c of the writing transistor T2, and a channel region T21b of the writing transistor T2 located between the first electrode region T21a of the writing transistor T2 and the second electrode region T21c of the writing transistor T2; and the active layer pattern T31 of the driving transistor T3 includes a first electrode region T31a of the driving transistor T3, a second electrode region T31c of the driving transistor T3, and a channel region T31b of the driving transistor T3 located between the first electrode region T31a of the driving transistor T3 and the second electrode region T31c of the driving transistor T3.

Gate patterns of the plurality of transistors of the pixel driving circuit are located in the gate film layer. The gate film layer includes, for example, a plurality of signal lines. A portion of a signal line passing through an active layer pattern of a transistor may serve as the gate of the transistor. The term “passing through” here refers to a portion of the signal line whose orthographic projection on the base substrate 101 overlaps with an orthographic projection of the active layer pattern on the base substrate 101. When manufacturing the transistors, the active film layer may be formed on the base substrate 101 to obtain the active layer patterns of the transistors, and then the gate film layer is formed on the side of the active film layer away from the base substrate 101; or, the gate film layer may be formed on the base substrate 101 to obtain the gate patterns of the transistors, and then the active film layer is formed on the side of the gate film layer away from the base substrate 101. A position where the gate film layer overlaps the active film layer is a position where the gate film layer “passes through” the active layer pattern. For example, the gate pattern of the transistor overlaps with the channel region of the transistor. For example, the gate pattern T12 of the sensing transistor T1 overlaps with the channel region T11b of the sensing transistor T1, the gate pattern T22 of the writing transistor T2 overlaps with the channel region T21b of the writing transistor T2, and the gate pattern T32 of the driving transistor T3 overlaps with the channel region T31b of the driving transistor T3.

The pixel driving circuit is mainly composed of transistors. Therefore, a space occupied by the transistors may determine a space occupied by the pixel driving circuit. For example, the space occupied by the transistors includes a horizontal region size parallel to a plane where the base substrate 101 is located and a longitudinal region size in a direction perpendicular to the plane where the base substrate 101 is located. The horizontal region size is an area of orthographic projections of the transistors on the base substrate 101, and the longitudinal region size is mainly related to the number of film layers included in the array substrate 10. An area of the active layer patterns of the transistors included in the pixel driving circuit may affect an area of the pixel driving circuit in an XY plane. The connection manner of each film layer in the array substrate may affect the number of film layers of the array substrate.

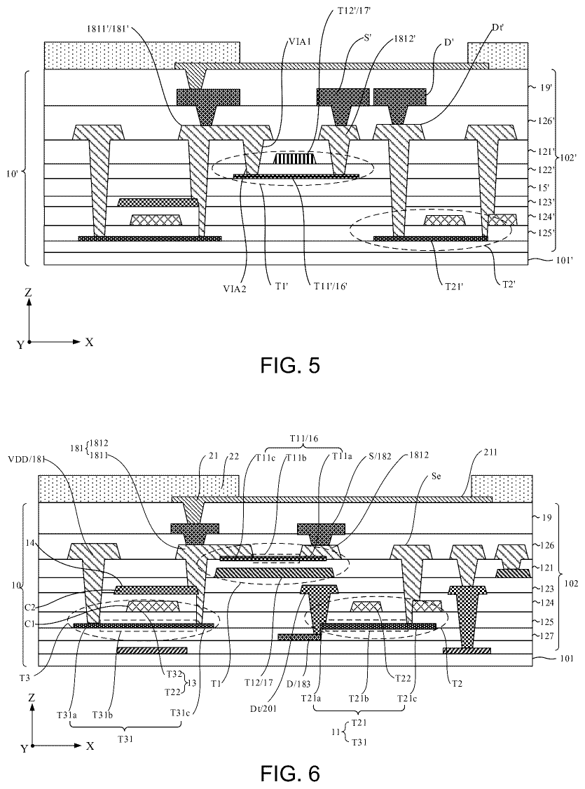

FIG. 5 is a structural diagram of a display panel provided in some embodiments.

As shown in FIG. 5, in some embodiments, the array substrate 10′ includes a base substrate 101′ and a pixel circuit stacked layer 102′, and the pixel circuit stacked layer 102′ is disposed on the base substrate 101′. The pixel circuit stacked layer 102′ includes a second active film layer 16′, a second gate film layer 17′ and a first source-drain metal layer 181′. A second insulating layer 122′ is provided between the second active film layer 16′ and the second gate film layer 17′. A first insulating layer 121′ is provided between the second gate film layer 17′ and the first source-drain metal layer 181′. The second active film layer 16′ includes an active layer pattern T11′ of a sensing transistor T1′, the second gate film layer 17′ includes a gate pattern T12′ of the sensing transistor T1′, and the first source-drain metal layer 181′ includes a first anode transfer pattern 1811′.

The first insulating layer 121′ is provided therein with a first via hole VIA1 penetrating the first insulating layer 121′, and the second insulating layer 122′ is provided therein with a second via hole VIA2 penetrating the second insulating layer 122′. A metal material is deposited in the first via hole VIA1 to form a first connection pattern, and a metal material is deposited in the second via hole VIA2 to form a second connection pattern. The first anode transfer pattern 1811′ is electrically connected to the active layer pattern T11′ of the sensing transistor T1′ through the first connection pattern and the second connection pattern. The first via hole VIA1 and the second via hole VIA2 occupy a certain area on the XY plane, so that an area of the pixel driving circuit on the XY plane increases. The active layer pattern T11′ of the sensing transistor T1′ requires a reserved space to be connected to the second connection pattern, so that the area of the active layer pattern of the transistor increases. In this way, for the array substrate 10′ of the same size, the horizontal region size of the space occupied by the transistors increases, and the number of pixel driving circuits provided in the array substrate 10′ decreases, which is disadvantageous for realizing a high Pixels Per Inch (PPI) of the display panel 100.

The second gate film layer 17′ is located on a side of the second active film layer 16′ away from the base substrate 101′. The active layer pattern T11′ of the sensing transistor T1′ cannot be directly connected to the first anode transfer pattern 1811′, and it need to be connected to the first anode transfer pattern 1811′ through via holes respectively penetrating the first insulating layer 121′ and the second insulating layer 122′, so that at least one layer may be added in the film layers of the array substrate 10′. As a result, a size of the array substrate 10′ in the third direction Z increases, which is disadvantageous for the thinness and lightness development of the array substrate.

In order to solve the above problems, some embodiments of the present disclosure provide an array substrate 10.

FIG. 6 is a structural diagram of a display panel provided in some embodiments of the present disclosure.

As shown in FIG. 6, the array substrate 10 includes a base substrate 101 and a pixel circuit stacked layer 102. The pixel circuit stacked layer 102 is disposed on the base substrate 101.

The base substrate 101 is used to support the pixel circuit stacked layer 102. For example, the base substrate 101 may be a rigid substrate made of a light-transmitting and non-metallic material with a certain degree of firmness, such as glass, quartz or common resin; alternatively, the base substrate 101 may be a flexible substrate made of a flexible material such as polyimide (PI).

The pixel circuit stacked layer 102 includes a transistor distribution layer and a first source-drain metal layer 181. The transistor distribution layer is disposed on a side of the base substrate 101, and the first source-drain metal layer 181 is disposed on a side of the transistor distribution layer away from the base substrate 101.

The sensing transistor T1 is arranged in the transistor distribution layer. The transistor distribution layer includes the active layer pattern T11 of the sensing transistor T1 and the gate pattern T12 of the sensing transistor T1. The active layer pattern T11 of the sensing transistor T1 is farther away from the base substrate 101 than the gate pattern T12 of the sensing transistor T1. In this case, the sensing transistor T1 is a bottom-gate transistor. It will be understood that the active layer pattern T11 of the sensing transistor T1 is closer to the first source-drain metal layer 181 than the gate pattern T12 of the sensing transistor T1. The active layer pattern T11 of the sensing transistor T1 is located in the second active film layer 16. The gate pattern T12 of the sensing transistor T1 is located in the second gate film layer 17. A first insulating layer 121 is provided between the second active film layer 16 and the second gate film layer 17.

The first source-drain metal layer 181 includes a first anode transfer pattern 1811 and a sensing line transfer pattern 1812. For example, the first source-drain metal layer 181 may be formed by depositing a metal material such as molybdenum (MO)/titanium (Ti)/aluminum (Al)/copper (Cu) using a thin film deposition process such as chemical vapor deposition (CVD), physical vapor deposition (PVD) or atomic layer deposition (ALD).

The sensing line transfer pattern 1812 is used to be connected to the sensing line S. The sensing line S is connected to the first electrode region T11a of the sensing transistor T1 through the sensing line transfer pattern 1812. The sensing line S is located in the second source-drain metal layer 182. The location of the second source-drain metal layer 182 will be described in detail later.

The first anode transfer pattern 1811 is connected to the active layer pattern T11 of the sensing transistor T1. The first anode transfer pattern 1811 is connected to the second electrode region T11c of the sensing transistor T1. The “connection” here means that the first anode transfer pattern 1811 and the active layer pattern T11 of the sensing transistor T1 directly overlap. That is, no additional insulating layer is provided between the first source-drain metal layer 181 and the active layer pattern T11 of the sensing transistor T1. In this case, there is no other insulating layer between the first source-drain metal layer 181 where the first anode transfer pattern 1811 is located and the active film layer of the transistor distribution layer where the active layer pattern T11 of the sensing transistor T1 is located.

The first anode transfer pattern 1811 and the active layer pattern T11 of the sensing transistor T1 directly overlap without a via hole. A certain area needs to be reserved for the via hole on the active layer pattern so that the transfer pattern in the via hole will be connected to the active layer pattern. When the second electrode region T11c of the sensing transistor T1 and the first anode transfer pattern 1811 directly overlap, the second electrode region T11c of the sensing transistor T1 is in contact with the first anode transfer pattern 1811. Compared with the case of the via hole, an area of the active layer pattern occupied for the direct overlap is smaller, which reduces the area occupied by the active layer pattern T11 of the sensing transistor T1 on the XY plane, and in turn reduces the area of the pixel driving circuit on the XY plane. For the array substrate 10 of the same size, the space occupied by the transistors on the XY plane is reduced, and the number of pixel driving circuits that can be arranged in the array substrate 10 is reduced, which is conducive to realizing a high PPI of the display panel 100.

In addition, no second insulating layer 122 is provided between the first source-drain metal layer 181 and the second active film layer 16 where the active layer pattern T11 of the sensing transistor T1 is located, so that the number of film layers of the array substrate 10 is reduced, and the size of the array substrate 10 in the third direction Z is reduced, which is beneficial for the thinness and lightness development of the display panel 100.

In some embodiments, referring to FIG. 6, the active layer pattern T11 of the sensing transistor T1 is connected to the sensing line transfer pattern 1812, and the sensing line transfer pattern 1812 is located in the first source-drain metal layer 181. The sensing line transfer pattern 1812 is connected to the first electrode region T11a of the sensing transistor T1. Since the sensing line transfer pattern 1812 is located in the first source-drain metal layer 181, the sensing line transfer pattern 1812 is in direct contact with the first electrode region T11a of the sensing transistor T1. Compared with the case of the via hole, an area of the active layer pattern occupied for the direct contact is smaller, which reduces the area occupied by the active layer pattern T11 of the sensing transistor T1 on the XY plane, and in turn reduces the area of the pixel driving circuit on the XY plane. For the array substrate 10 of the same size, the space occupied by the transistors on the XY plane is reduced, and the number of pixel driving circuits that can be arranged in the array substrate 10 is reduced, which is conducive to realizing a high PPI of the display panel 100.

In some other embodiments, the pixel driving circuit adopts a 7T1C or 8T1C internal compensation circuit, and the internal compensation circuit adopts a low temperature polycrystalline oxide (LTPO) process or a low temperature poly-silicon (LTPS) process. However, this internal compensation circuit has a large number of transistors, and the horizontal region size of the space occupied by the transistors increases, so that the area occupied by the pixel driving circuit is larger, and the PPI of the display panel 100 may only stop at 600 PPI, which is disadvantageous for realizing a high PPI of the display panel 100.

The pixel driving circuit adopts a 3T1C external compensation circuit, and the external compensation circuit adopts an oxide process. The smaller the oxide transistor device is, the worse the device stability is. Therefore, in order to improve the device stability, the oxide transistor device needs to maintain a certain size and cannot be made smaller. In addition, the oxide transistor has a low electron mobility and a long transistor compensation time. As a result, the oxide transistors may only be used in large-size and low-PPI products (such as TVs).

To solve the above problem, in some embodiments, the transistor distribution layer includes a plurality of transistor distribution sub-layers (e.g., two or more transistor distribution sub-layers). Each transistor distribution sub-layer includes an active film layer and a gate film layer that are stacked. The active film layer includes an active layer pattern of a transistor, and the gate film layer includes a gate pattern of a transistor. Active film layers of the plurality of transistor distribution sub-layers are stacked. For example, referring to FIG. 6, the plurality of transistor distribution sub-layers include a first transistor distribution sub-layer and a second transistor distribution sub-layer. The first transistor distribution sub-layer includes a first transistor active sub-film layer (hereinafter referred to as a first active film layer) 11 and a first transistor gate sub-film layer (hereinafter referred to as a first gate film layer) 13 that are stacked. The second transistor distribution sub-layer includes a second transistor active sub-film layer (hereinafter referred to as a second active film layer) 16 and a second transistor gate sub-film layer (hereinafter referred to as a second gate film layer) 17 that are stacked. The first active film layer 11 and the second active film layer 16 are stacked. For example, the first active film layer 11 is closer to the base substrate 101 than the second active film layer 16.

An active film layer of at least one transistor distribution sub-layer is a polysilicon active film layer, and an active film layer of at least one transistor distribution sub-layer is an oxide active film layer. The polysilicon active film layer may be made of an LTPS, and the oxide active film layer may be made of indium gallium zinc oxide (IGZO), wherein IGZO is a high mobility active layer material. For example, the first active film layer 11 is a polysilicon active film layer, and the second active film layer 16 is an oxide active film layer. As another example, the first active film layer 11 is an oxide active film layer, and the second active film layer 16 is a polysilicon active film layer. The active layer patterns located in the oxide active film layer are made of oxide, and the active layer patterns located in the polysilicon active film layer are made of polysilicon.

The active layer patterns of the sensing transistor T1, the writing transistor T2 and the driving transistor T3 in the pixel driving circuit are at least located in active film layers of two transistor distribution sub-layers. That is to say, the active layer pattern T11 and the gate pattern T12 of the sensing transistor T1 are respectively located in the active film layer and the gate film layer of one transistor distribution sub-layer, the active layer pattern T21 and the gate pattern T22 of the writing transistor T2 are respectively located in the active film layer and the gate film layer of one transistor distribution sub-layer, and the active layer pattern T31 and the gate pattern T32 of the driving transistor T3 are respectively located in the active film layer and the gate film layer of one transistor distribution sub-layer.

At least one of the active layer pattern T11 of the sensing transistor T1, the active layer pattern T21 of the writing transistor T2, and the active layer pattern T31 of the driving transistor T3 is made of polysilicon. At least one of the active layer pattern T11 of the sensing transistor T1, the active layer pattern T21 of the writing transistor T2, and the active layer pattern T31 of the driving transistor T3 is made of oxide.

For example, the materials of the active layer patterns of the sensing transistor T1, the writing transistor T2, and the driving transistor T3 may be LTPS and oxide. That is, among the sensing transistor T1, the writing transistor T2, and the driving transistor T3, at least one transistor is a low-temperature polysilicon transistor, and at least one transistor is an oxide transistor. LTPS has high electron mobility, which may reduce transistor compensation time and improve the yield and stability of the pixel driving circuit.

In some examples, the active layer pattern T11 of the sensing transistor T1 and the active layer pattern T21 of the writing transistor T2 are made of different materials.

For example, the active layer pattern T11 of the sensing transistor T1 may be made of oxide. That is to say, the sensing transistor T1 may be an oxide transistor. For example, the active layer pattern T11 of the sensing transistor T1 may be made of IGZO. The active layer pattern T11 of the sensing transistor T1 is connected to the anode 211 through the first anode transfer pattern 1811. An off-state current (Ioff) of IGZO is relatively low, thereby reducing the leakage current of the sensing transistor T1 and ensuring the anode potential. The active layer pattern T21 of the writing transistor T2 and the active layer pattern T31 of the driving transistor T3 may be made of LTPS. That is, the writing transistor T2 and the driving transistor T3 may be low temperature polysilicon transistors.

As another example, the active layer pattern T11 of the sensing transistor T1 may be made of LTPS, and the active layer pattern of the writing transistor T2 and the active layer pattern T31 of the driving transistor T3 may be made of IGZO. That is, the sensing transistor T1 is a low-temperature polysilicon transistor, and the writing transistor T2 and the driving transistor T3 are oxide transistors.

In some examples, the active layer pattern T11 of the sensing transistor T1 and the active layer pattern T21 of the writing transistor T2 are made of the same material.

For example, the sensing transistor T1 and the writing transistor T2 are transistors of the same type, e.g., low temperature polysilicon transistors. The driving transistor T3 is a transistor of another type, e.g., an oxide transistor.

The low-temperature polysilicon transistors have the advantages such as high mobility and fast charging, and the oxide transistors have the advantages such as low leakage current. The low-temperature polysilicon transistors and the oxide transistors are integrated on an array substrate 10 to form an LTPO array substrate. Due to the advantages of the low-temperature polysilicon transistors and the oxide transistors, the refresh frequency of the array substrate 10 may be switched to achieve low-frequency driving, which is conducive to reducing power consumption and improving display quality.

It will be noted that “the transistor distribution layer includes a plurality of transistor distribution sub-layers” means that the number of transistor distribution sub-layers in the transistor distribution layer is greater than or equal to two. For example, the number of transistor distribution sub-layers in the transistor distribution layer may be two, three, four, five or six, which may be set according to actual needs, and will not be specifically limited in the embodiments of the present disclosure.

Referring to FIG. 6, the transistor distribution layer further includes a first transfer layer 14, the second electrode plate C2 of the storage capacitor C in the pixel driving circuit is arranged in the first transfer layer 14, and the second electrode plate C2 is connected to the first anode transfer pattern 1811 through via hole(s). The gate pattern T32 of the driving transistor T3 may also be used as the first electrode plate C1 of the storage capacitor C. The active layer pattern T31 of the driving transistor T3 is connected to the first transfer layer 14 through via hole(s).

In some embodiments, referring to FIG. 6, the first gate film layer 13 and the second gate film layer 17 are located between the first active film layer 11 and the second active film layer 16. The first active film layer 11 and the second active film layer 16 are stacked so that a plurality of transistors (including low-temperature polysilicon transistors and oxide transistors) are located in different transistor distribution sub-layers in the third direction Z, which reduces the area occupied by the plurality of transistors arranged on the XY plane. Therefore, the number of pixel driving circuits in the array substrate 10 is increased, and the PPI of the display panel 100 is improved.

The writing transistor T2 and the driving transistor T3 are located in the first transistor distribution sub-layer. It will be understood that the active layer pattern T21 of the writing transistor T2 and the active layer pattern T31 of the driving transistor T3 are both located in the first active film layer 11, and the gate pattern T22 of the writing transistor T2 and the gate pattern T32 of the driving transistor T3 are both located in the first gate film layer 13.

The sensing transistor T1 is located in the second transistor distribution sub-layer. It will be understood that the active layer pattern T11 of the sensing transistor T1 is located in the second active film layer 16, and the gate pattern T12 of the sensing transistor T1 is located in the second gate film layer 17.

In some examples, referring to FIG. 6, the first gate film layer 13 and the second gate film layer 17 are located in different layers. In this case, the gate pattern T12 of the sensing transistor T1 and the gate pattern T22 of the writing transistor T2 are located in different film layers. The first gate film layer 13 and the second gate film layer 17 are sequentially stacked between the first active film layer 11 and the second active film layer 16. For example, the first active film layer 11, the first gate film layer 13, the second gate film layer 17 and the second active film layer 16 are sequentially stacked on the base substrate 101. The first transfer layer 14 may be located between the first transistor distribution sub-layer and the second transistor distribution sub-layer. For example, the first transfer layer 14 is located between the first gate film layer 13 and the second gate film layer 17.

The first insulating layer 121 is provided between the second active film layer 16 and the second gate film layer 17, and the first insulating layer 121 covers the second gate film layer 17. A third insulating layer 123 is provided between the second gate film layer 17 and the first transfer layer 14, and the third insulating layer 123 covers the first transfer layer 14. A fourth insulating layer 124 is provided between the first transfer layer 14 and the first gate film layer 13, and the fourth insulating layer 124 covers the first gate film layer 13. A fifth insulating layer 125 is provided between the first gate film layer 13 and the first active film layer 11, and the fifth insulating layer 125 covers the first active film layer 11.

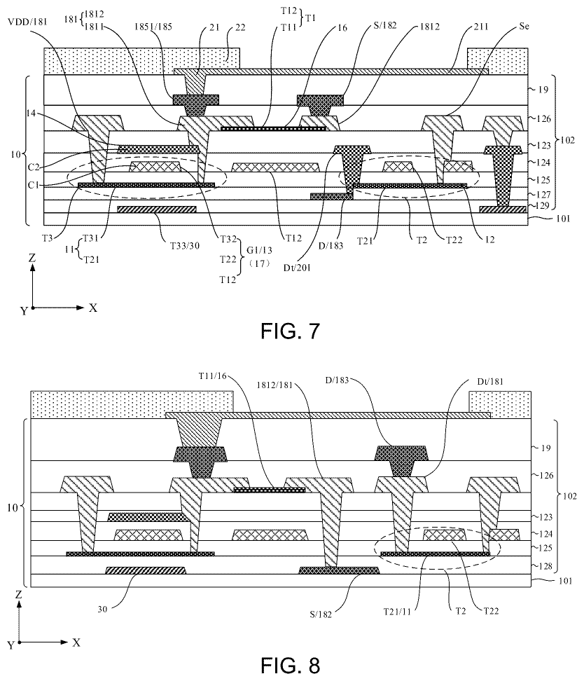

FIG. 7 is a structural diagram of yet another display panel according to some embodiments of the present disclosure.

In some other examples, as shown in FIG. 7, the first gate film layer 13 and the second gate film layer 17 are located in the same layer. In this case, the gate pattern T12 of the sensing transistor T1, the gate pattern T22 of the writing transistor T2, and the gate pattern T32 of the driving transistor T3 are located in the same film layer (hereinafter referred to as a third gate film layer G1). Furthermore, among the active layer patterns of the sensing transistor T1, the writing transistor T2 and the driving transistor T3, at least one active layer pattern is located in the polysilicon active film layer, and at least one active layer pattern is located in the oxide active film layer; therefore, the gate pattern of the low-temperature polysilicon transistor and the gate pattern of the oxide transistor share the third gate film layer G1.

The first transfer layer 14 is located between the first active film layer 11 and the second active film layer 16. For example, the first transfer layer is located between the third gate film layer G1 and the second active film layer 16.

Of course, insulating layers are provided between the first active film layer 11, the third gate film layer G1, the first transfer layer 14 and the second active film layer 16. A third insulating layer 123 is provided between the second active film layer 16 and the first transfer layer 14, and the third insulating layer 123 covers the first transfer layer 14. A fourth insulating layer 124 is provided between the first transfer layer 14 and the third gate film layer G1, and the fourth insulating layer 124 covers the third gate film layer G1. A fifth insulating layer 125 is provided between the third gate film layer G1 and the first active film layer 11, and the fifth insulating layer 125 covers the first active film layer 11. A first insulating layer 121 originally provided between the second active film layer 16 and the second gate film layer 17 is omitted. Therefore, the number of film layers of the array substrate 10 is reduced, and the size of the array substrate 10 in the third direction Z is reduced, which is beneficial for the lightness and thinness design of the display panel 100.

In some embodiments, referring to FIG. 7, the array substrate 10 further includes a second source-drain metal layer 182 and a third source-drain metal layer 183. The second source-drain metal layer 182 includes sensing lines S, and the third source-drain metal layer 183 includes data signal lines D. The active layer pattern T11 of the sensing transistor T1 is connected to the sensing line S through the sensing line transfer pattern 1812. The active layer pattern T21 of the writing transistor T2 is connected to the data signal line D through a data signal transfer pattern Dt. The data signal transfer pattern Dt is located in a first transfer gate film layer. The first transfer gate film layer is located between active film layers of adjacent transistor distribution sub-layers. Alternatively, the first transfer gate film layer and the first source-drain metal layer 181 are located in the same layer.

In some embodiments, referring to FIG. 5, the sensing line S′ and the data signal line D′ are located on the same side of the transistor distribution layer away from the base substrate 101′. The sensing line transfer pattern 1812′ needs to be connected to the sensing line S′ through a via hole disposed on a side of the sensing line transfer pattern 1812′ away from the base substrate 101′. The data signal transfer pattern Dt′ needs to be connected to the data signal line D′ through a via hole disposed on a side of the data signal transfer pattern Dt′ away from the base substrate 101′. In this way, a plurality of via holes are arranged on the same side of the transistor distribution layer away from the base substrate 101′, resulting in a large number of via holes (hereinafter referred to as same-direction via holes) located on the side of the transistor distribution layer away from the base substrate 101′ in the array substrate 10. Orthogonal projections of the same-direction via holes on the base substrate 101′ do not overlap. Therefore, an arrangement space needs to be reserved for a plurality of same-direction via holes on the XY plane, which leads to a large space occupied by the pixel driving circuit on the XY plane. In addition, the sensing line S′ and the data signal line D′ are both located in the same source-drain metal layer, and orthogonal projections of the sensing line S′ and the data signal line D′ on the base substrate 101′ do not overlap, so that the number of pixel driving circuits that can be arranged in the array substrate 10′ is further reduced, which is disadvantageous for realizing a high PPI of the display panel 100.

To solve the above technical problems, in some embodiments, one of the sensing line S and the data signal line D is located on a side of the transistor distribution layer close to the base substrate 101, and another of the sensing line S and the data signal line D is located on a side of the first source-drain metal layer 181 away from the base substrate 101. That is, the second source-drain metal layer 182 and the third source-drain metal layer 183 are respectively located on two sides of the transistor distribution layer.

For example, referring to FIG. 7, the second source-drain metal layer 182 is located on a side of the first source-drain metal layer away from the base substrate 101 (“a side away from the base substrate 101” is hereinafter referred to as an upper side); and the third source-drain metal layer 183 is located on a side of the transistor distribution layer close to the base substrate 101 (“a side close to the base substrate 101” is hereinafter referred to as a lower side). In consideration of the process stability, the second source-drain metal layer 182 may be made of Mo.

When the first gate transfer film layer 201 is located between the second active film layer 16 and the first active film layer 11, for example, the first gate transfer film layer 201 is located between the first active film layer 16 and the third gate film layer G1, the sensing line transfer pattern 1812 and the data signal transfer pattern Dt are located in different film layers. The sensing line transfer pattern 1812 is located on a side of the data signal transfer pattern Dt away from the base substrate 101. In some examples, the first gate transfer film layer 201 and the first transfer layer 14 are located in the same layer. When forming the first transfer layer 14, the second electrode plate C2 and the data signal transfer pattern Dt may be formed simultaneously, thereby reducing the process steps and improving product production efficiency.

A sixth insulating layer 126 is provided between the second source-drain metal layer 182 and the first source-drain metal layer 181. The sensing line S is connected to the sensing line transfer pattern 1812 through a via hole penetrating the sixth insulating layer 126. The via hole is located on an upper side of the sensing line transfer pattern 1812. A seventh insulating layer 127 is provided between the third source-drain metal layer 183 and the first active film layer 11. The data signal transfer pattern Dt is connected to the data signal line D through via holes respectively penetrating the fourth insulating layer 124, the fifth insulating layer 125 and the seventh insulating layer 127. The via holes are located on a lower side of the data signal transfer pattern Dt. The via hole for the sensing line transfer pattern 1812 connecting the sensing line S is located on the upper side, and the via holes for the data signal transfer pattern Dt connecting the data signal line D is located on the lower side, so that they are not the same-direction via holes.

When the first gate transfer film layer 201 and the sensing line transfer pattern 1812 are located in the same film layer (both are located in the first source-drain metal layer 181), the via hole for the sensing line transfer pattern 1812 connecting the sensing line S is located on the upper side, and the via holes for the data signal transfer pattern Dt connecting the data signal line D is located on the lower side, so that they are not the same-direction via holes. When forming the first source-drain metal layer 181, the first anode transfer pattern 1811, the sensing line transfer pattern 1812 and the data signal transfer pattern Dt may be formed simultaneously, thereby reducing process steps and improving product production efficiency.

In this way, when the via hole for the sensing line transfer pattern 1812 connecting the sensing line S and the via holes for the data signal transfer pattern Dt connecting the data signal line D are not the same-direction via holes, the number of same-direction via holes in the array substrate 10 may be reduced. Orthogonal projections, on the base substrate 101, of the via holes on two sides may overlap, and non-same-direction via holes occupy a smaller space on the XY plane, thereby reducing the area occupied by the pixel driving circuit on the XY plane. In addition, the sensing line S and the data signal line D are located in different source-drain metal layers, and the orthogonal projections of the sensing line S and the data signal line D on the base substrate 101 may overlap, thereby reducing the area occupied by the pixel driving circuit on the XY plane. Thus, it is conducive to increasing the number of pixel driving circuits that can be arranged in the array substrate 10 and in turn improving the PPI of the display panel 100.

FIG. 8 is a structural diagram of yet another display panel according to some embodiments of the present disclosure.

As another example, as shown in FIG. 8, the second source-drain metal layer 182 is located on the upper side of the transistor distribution layer, and the third source-drain metal layer 183 is located on the lower side of the first source-drain metal layer 181. The second source-drain metal layer 182 may be made of a metal conductive material such as Ti, Al, Cu or Mo. A type of the material available for the second source-drain metal layer 182 varies.

When the first gate transfer film layer 201 and the sensing line transfer pattern 1812 are located in the same film layer (both are located in the first source-drain metal layer 181), an eighth insulating layer 128 is provided between the sensing line S and the first active film layer 11, and the sensing line S is connected to the sensing line transfer pattern 1812 through via holes respectively penetrating the eighth insulating layer 128, the fifth insulating layer 125, the fourth insulating layer 124, and the third insulating layer 123. The via holes are located on the lower side of the sensing line transfer pattern 1812. The data signal line D is connected to the data signal transfer pattern Dt through a via hole penetrating the sixth insulating layer 126, and the via hole is located on the upper side of the data signal transfer pattern Dt. The via holes for the sensing line transfer pattern 1812 connecting the sensing line S are located on the lower side of the sensing line transfer pattern 1812, and the via hole for the data signal transfer pattern Dt connecting the data signal line D is located on the upper side of the data signal transfer pattern Dt, so that they are not the same-direction via holes. The number of same-direction via holes in the array substrate 10 may be reduced. Orthogonal projections, on the base substrate 101, of the via holes on two sides may overlap, and non-same-direction via holes occupy a smaller space on the XY plane, thereby reducing the area occupied by the pixel driving circuit on the XY plane. In addition, the sensing line S and the data signal line D are located in different source-drain metal layers, and the orthogonal projections of the sensing line S and the data signal line D on the base substrate 101 may overlap, thereby reducing the area occupied by the pixel driving circuit on the XY plane. Thus, it is conducive to increasing the number of pixel driving circuits that can be arranged in the array substrate 10 and in turn improving the PPI of the display panel 100.

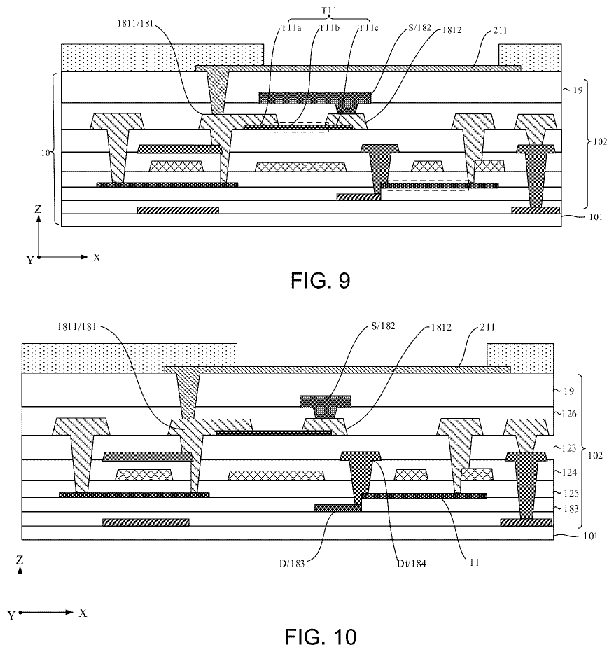

FIG. 9 is a structural diagram of yet another display panel according to some embodiments of the present disclosure.

In some embodiments, as shown in FIG. 9, when the second source-drain metal layer 182 is disposed on the upper side of the first source-drain metal layer 181, an orthogonal projection of the sensing line S on the base substrate 101 covers an orthogonal projection of the channel region T11b of the active layer pattern of the sensing transistor T1 on the base substrate 101. The sensing line S serves as a light-shielding layer of the active layer pattern T11 of the sensing transistor T1, which may block light emitted from the side of the first source-drain metal layer 181 away from the base substrate 101 to the sensing transistor T1, thereby improving the stability of the sensing transistor T1.

In some embodiments, referring to FIG. 6, the active layer pattern T21 of the writing transistor T2 is connected to the gate pattern T32 of the driving transistor T3 through a first transfer pattern Se. The second electrode region T12c of the writing transistor T2 is connected to the gate pattern T32 of the driving transistor T3 through the first transfer pattern Se. The first transfer pattern Se is located in the first source-drain metal layer 181. For example, the first transfer pattern Se is connected to the active layer pattern T21 of the writing transistor T2 through via holes respectively penetrating the third insulating layer 123, the fourth insulating layer 124 and the fifth insulating layer 125, and the first transfer pattern Se is connected to the gate pattern T32 of the driving transistor T3 through via holes respectively penetrating the third insulating layer 123 and the fourth insulating layer 124. When forming the first source-drain metal layer 181, the first anode transfer pattern 1811, the sensing line transfer pattern 1812 and the first transfer pattern Se may be formed simultaneously, thereby reducing the process steps and improving product production efficiency.

In some embodiments, referring to FIG. 6, the active layer pattern T31 of the driving transistor T3 is connected to the first voltage signal line VDD through via holes; and the active layer pattern T31 of the driving transistor T3 is further connected to the first anode transfer pattern 1811 through via holes. The first electrode region T31a of the driving transistor T3 is connected to the first voltage signal line VDD through via holes, and the second electrode region T31c of the driving transistor T3 is connected to the first anode transfer pattern 1811 through via holes. For example, the first voltage signal line VDD is located in the first source-drain metal layer 181.

That is to say, the first anode transfer pattern 1811, the sensing line transfer pattern 1812 and the first voltage signal line VDD are all located in the first source-drain metal layer 181. In this way, when forming the first source-drain metal layer 181, the first anode transfer pattern 1811, the sensing line transfer pattern 1812 and the first voltage signal line VDD may be formed simultaneously, thereby reducing the process steps and improving product production efficiency.

In some implementations, the first anode transfer pattern 1811, the sensing line transfer pattern 1812, the first transfer pattern Se, the data signal transfer pattern Dt, and the first voltage signal line VDD are all located in the same layer. In this way, when forming the first source-drain metal layer 181, the first anode transfer pattern 1811, the sensing line transfer pattern 1812, the first transfer pattern Se, the data signal transfer pattern Dt and the first voltage signal line VDD may be formed simultaneously, thereby reducing the process steps and improving product production efficiency. Moreover, the film layers where the first anode transfer pattern 1811, the sensing line transfer pattern 1812, the first transfer pattern Se, the data signal transfer pattern Dt and the first voltage signal line VDD are located are all functional layers. When these functional layers are located in the same layer, there is no need to provide an insulating layer between adjacent functional layers. Therefore, the number of film layers of the array substrate 10 is reduced, and the size of the array substrate 10 in the third direction Z is reduced, which facilitates the lightness and thinness development of the display panel 100.

In some embodiments, referring to FIG. 7, the array substrate 10 further includes a light-shielding layer 30. The light-shielding layer 30 is disposed on a lower side of the transistor distribution layer. The light-shielding layer 30 may block light that is emitted from a side of the base substrate 101 away from the light-shielding layer 30 toward the array substrate 10. For example, the light-shielding layer 30 may be made of one or more of Ti, Al, Cu, or Mo. At least one transistor (e.g., one, or more transistors) among the plurality of transistors is a dual-gate transistor. The dual-gate transistor is disposed in a transistor distribution sub-layer closest to the base substrate 101. The gate film layer of the transistor distribution sub-layer closest to the base substrate includes a top-gate pattern of the dual-gate transistor, and the light-shielding layer 30 includes a bottom-gate pattern of the dual-gate transistor.

Here, “the transistor distribution sub-layer closest to the base substrate 101” refers to a transistor distribution sub-layer, where an active film layer closest to the base substrate 101 is located, among the plurality of stacked transistor distribution sub-layers.

For example, referring to FIG. 7, an active film layer closest to the base substrate 101 is the first active film layer 11. Thus, a transistor distribution sub-layer closest to the base substrate 101 is the first transistor distribution sub-layer.

In some examples, the driving transistor T3 may be a dual-gate transistor. The driving transistor T3 includes the active layer pattern T31 of the driving transistor T3, the gate pattern T32 (the top-gate pattern) of the driving transistor T3, and the bottom gate pattern T33 of the driving transistor T3. The active layer pattern T31 of the driving transistor T3 is arranged in the first active film layer 11, the gate pattern T32 (the top-gate pattern) of the driving transistor is arranged in the first gate film layer 13, and the bottom-gate pattern T33 of the driving transistor T3 is arranged in the light-shielding layer 30. The bottom-gate pattern T33 overlaps the active layer pattern T31 of the driving transistor T3. The bottom-gate pattern T33 overlaps the channel region T31b of the active layer pattern T31 of the driving transistor T3, thereby blocking the light directed to the driving transistor T3 and avoiding changes in the characteristics of the driving transistor T3 caused by light.

In some other examples, the writing transistor T2 may be a dual-gate transistor, and the writing transistor T2 includes the active layer pattern T21 of the writing transistor T2, the gate pattern T22 (the top-gate pattern) of the writing transistor T2, and the bottom-gate pattern of the writing transistor T2. The active layer pattern T21 of the writing transistor T2 is arranged in the first active film layer 11, the gate pattern T22 (the top-gate pattern) of the writing transistor T2 is arranged in the first gate film layer 13, and the bottom-gate pattern T33 of the writing transistor T2 is arranged in the light-shielding layer 30. The bottom-gate pattern T33 of the writing transistor T2 overlaps the channel region T21b of the active layer pattern T21 of the writing transistor T2, thereby blocking light directed to the writing transistor T2 and avoiding changes in the characteristics of the writing transistor T2 caused by light.

In some other examples, both the driving transistor T3 and the writing transistor T2 are dual-gate transistors. The bottom-gate pattern T33 of the driving transistor T3 and the bottom-gate pattern T23 of the writing transistor T2 are both located in the light-shielding layer 30.

By driving the active layer pattern through the top-gate pattern and the bottom-gate pattern, the threshold voltage may be easily controlled, and the carrier mobility may also be improved. That is, compared with a top-gate transistor and a bottom-gate transistor, the dual-gate transistor has higher stability.

In some embodiments, referring to FIG. 8, the light-shielding layer 30 and the second source-drain metal layer 182 are located in the same layer. That is, the second source-drain metal layer 182 is also located on the lower side of the transistor distribution layer. When forming the second source-drain metal layer 182, the light-shielding layer 30 may be formed simultaneously, thereby reducing the process steps and improving product production efficiency.

In some embodiments, referring to FIG. 7, the array substrate 10 further includes a fifth source-drain metal layer 185. The fifth source-drain metal layer 185 is disposed on an upper side of the first source-drain metal layer 181. The fifth source-drain metal layer 185 includes a second anode transfer pattern 1851. The second anode transfer pattern 1851 is connected to the first anode transfer pattern 1811 through a via hole penetrating the sixth insulating layer 126.

The array substrate 10 further includes a planarization layer 19, which is mainly used to block water, oxygen and alkaline ions. The planarization layer 19 is disposed on the upper side of the first source-drain metal layer 181. The planarization layer 19 is located between the anode layer 21 and the fifth source-drain metal layer 185. The planarization layer 19 covers the fifth source-drain metal layer 185. The planarization layer 19 may be formed by applying PI using a spin coating process, or may be formed by depositing silicon nitride, silicon oxide or silicon oxynitride using a thin film substrate process.

The first anode transfer pattern 1811 is connected to an anode 211 in the anode layer 21 through the second anode transfer pattern 1851.

In some examples, the second source-drain metal layer 182 and the fifth source-drain metal layer 185 are located in the same layer. It will be understood that the sensing line S and the second anode transfer pattern 1851 are located in the same layer, and the planarization layer 19 covers the fifth source-drain metal layer 185 and the sensing line S. When forming the second source-drain metal layer 182, the sensing line S and the second anode transfer pattern 1851 may be formed simultaneously, thereby reducing the process steps and improving product production efficiency.

In some other examples, the second source-drain metal layer 182 and the fifth source-drain metal layer 185 may be located in different layers. The fifth source-drain metal layer 185 is disposed on the upper side of the second source-drain metal layer 182.

FIG. 10 is a structural diagram of yet another display panel according to some embodiments of the present disclosure.

In some embodiments, as shown in FIG. 10, the array substrate 10 further includes a planarization layer 19. The planarization layer 19 is disposed on the upper side of the first source-drain metal layer 181, and the planarization layer 19 covers the sensing lines S. No fifth source-drain metal layer is provided in the pixel circuit stacked layer 102. The first anode transfer pattern 1811 is connected to the anode 211 through a via hole penetrating the planarization layer 19. During the manufacturing process, after the second source-drain metal layer 182 is formed, the planarization layer 19 is directly formed to reduce the manufacturing process.

A region corresponding to each sub-pixel SP on the array substrate 10 is a sub-pixel region. Sub-pixel regions are also arranged in a plurality of rows and a plurality of columns. Considering a 2 by 2 (2*2) pixel design of the display panel as an example, 2 by 2 pixels include a first pixel, a second pixel, a third pixel and a fourth pixel. A region corresponding to the first pixel on the array substrate 10 is a first pixel region P1, a region corresponding to the second pixel on the array substrate 10 is a second pixel region P2, a region corresponding to the third pixel on the array substrate 10 is a third pixel region P3, and a region corresponding to the fourth pixel on the array substrate 10 is a fourth pixel region P4. The first pixel region P1 and the second pixel region P2 are arranged in the same row, and the third pixel region P3 and the fourth pixel region P4 are arranged in the same row. The first pixel region P1 and the fourth pixel region P4 are arranged in the same column, and the second pixel region P2 and the third pixel region P3 are arranged in the same column.

Each pixel region includes three sub-pixel regions arranged in the first direction X.

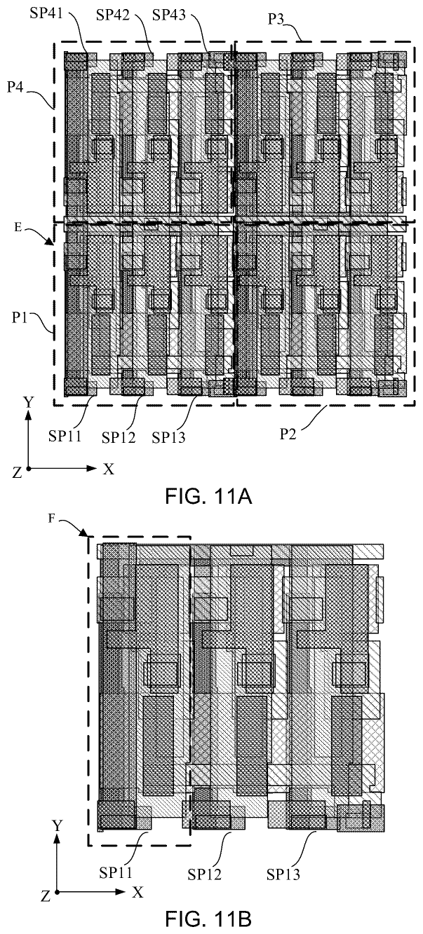

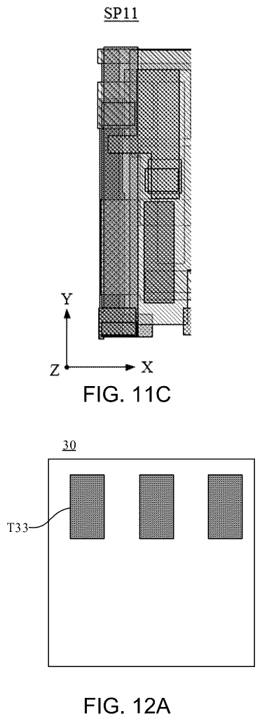

FIG. 11A is a structural diagram of stacked film layers in a plurality of sub-pixel regions of an array substrate according to some embodiments of the present disclosure. FIG. 11B is an enlarged view of the region E in FIG. 11A. FIG. 11C is an enlarged view of the region F in FIG. 11B.

For example, as shown in FIGS. 11A and 11B, the first pixel region P1 includes a first sub-pixel region SP11, a second sub-pixel region SP12, and a third sub-pixel region SP13.

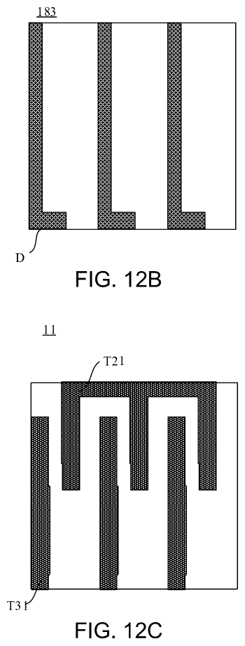

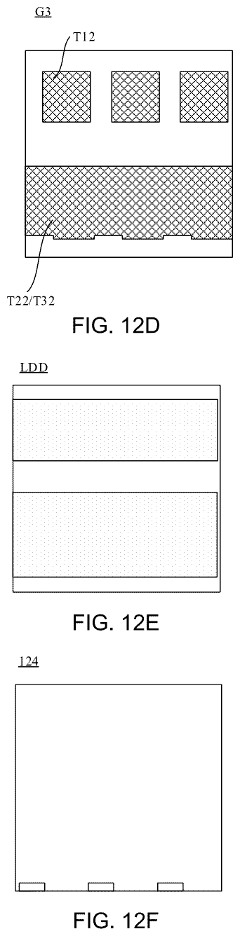

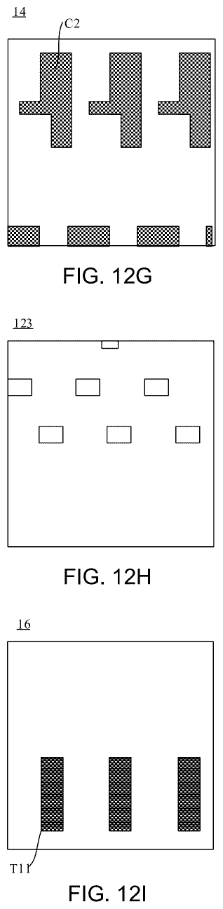

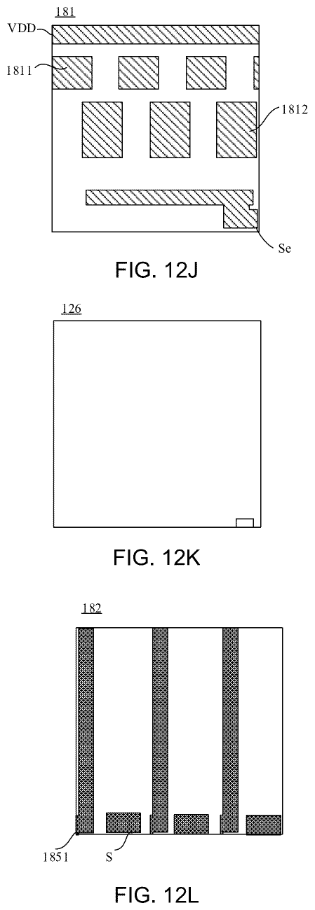

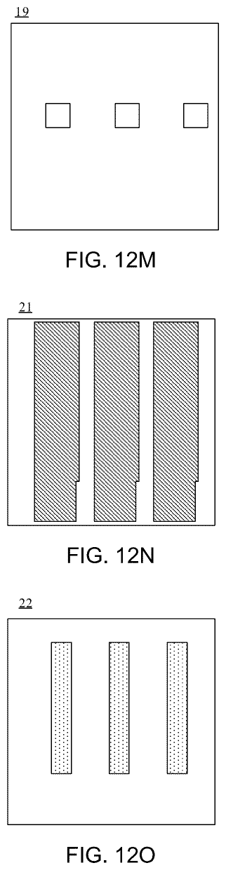

FIGS. 12A to 12O are structural diagrams of film layers according to some embodiments of the present disclosure.

FIGS. 12A to 12O are structural diagrams of film layers in FIG. 7. Considering the first pixel region P1 as an example, steps of forming film layer patterns in the first pixel region P1 are as follows.

In S1, an initial light-shielding layer is formed on the base substrate 101 through deposition, and a light-shielding layer 30 is formed through a patterning process. Patterns of the light-shielding layer 30 in the first sub-pixel region SP11, the second sub-pixel region SP12, and the third sub-pixel region SP13 are formed simultaneously. The film structure of the light-shielding layer 30 is shown in FIG. 12A. The light-shielding layer 30 may include a bottom-gate pattern T33 of a driving transistor T3. The light-shielding layer 30 may be made of a metal conductive material such as Ti, Al, Cu or Mo. As for the structure of the light-shielding layer 30, reference is made of the above description, and details will not be repeated here.

In S2, the ninth insulating layer 129 is formed on the base substrate 101. The ninth insulating layer 129 covers the light-shielding layer 30. As for the material of the ninth insulating layer 129, reference may be made to the description of the above inorganic insulating material, which will not be repeated here.

In S3, an initial third source-drain metal layer is formed, and the third source-drain metal layer 183 is formed through a patterning process. The film structure of the third source-drain metal layer 183 is shown in FIG. 12B. The third source-drain metal layer 183 includes data signal lines D for connecting to subsequently formed data signal transfer patterns Dt. As for the material of the third source-drain metal layer 183, reference may be made to the material of the light-shielding layer 30, and details will not be repeated here. As for the structure of the third source-drain metal layer 183, reference may be made to the above description, which will not be repeated here.

In S4, the seventh insulating layer 127 is formed. The seventh insulating layer 127 covers the third source-drain metal layer 183.

In S5, an initial first active film layer is formed, and the first active film layer 11 is formed through a patterning process. The first active film layer 11 includes the active layer pattern T31 of the driving transistor T3 and the active layer pattern T21 of the writing transistor T2. The film structure of the first active film layer 11 is shown in FIG. 12C. As for the material of the first active film layer 11, reference may be made to the above description, and details will not be repeated here. As for the structure of the first active film layer 11, reference may be made to the above description, which will not be repeated here.

In some implementations, an active film layer including the active layer pattern T31 of the driving transistor T3 and an active film layer including the active layer pattern T21 of the writing transistor T2 may be formed separately. The two active film layers are separated by an insulating layer.

In S6, a fifth insulating layer 125 is formed, and the fifth insulating layer 125 covers the first active film layer 11.

In S7, an initial third gate film layer is formed, and a third gate film layer G3 is formed through a patterning process. The third gate film layer G3 includes the gate pattern T32 of the driving transistor T3, the gate pattern T12 of the sensing transistor T1, and the gate pattern T22 of the writing transistor T2. The film structure of the third gate film layer G3 is shown in FIG. 12D. The gate pattern T32 of the driving transistor T3 and the gate pattern T22 of the writing transistor T2 are connected to each other. As for the material of the third gate film layer G3, reference may be made to the material of the light-shielding layer 30, and details will not be repeated here. As for the structure of the third gate film layer G3, reference may be made to the above description, which will not be repeated here.

In some implementations, a gate film layer including the gate pattern T32 of the driving transistor T3, a gate film layer including the gate pattern T12 of the sensing transistor T1, and a gate film layer including the gate pattern T22 of the writing transistor T2 may be formed separately. Adjacent gate film layers are separated by an insulating layer.

In some implementations, there may be a lightly doped drain (LDD) structure in the channel region of the transistor close to the drain. The film layer structure of the LDD is shown in FIG. 12E. The LDD structure is a low-doped drain region in the channel of the transistor close to the drain. The low-doped drain region is also subjected to some voltage. This structure may prevent the hot electron degradation effect.

In S8, a fourth insulating layer 124 is formed, and the fourth insulating layer 124 covers the third gate film layer G3. The film structure of the fourth insulating layer 124 is shown in FIG. 12F. The fourth insulating layer 124 is provided therein with via holes for connection between functional layers.

In S9, an initial first transfer layer is formed, and a first transfer layer 14 is formed through a patterning process. The first transfer layer 14 includes second electrode plates C2 of storage capacitors C. The film structure of the first transfer layer 14 is shown in FIG. 12G. As for the material of the first transfer layer 14, reference may be made to the material of the light-shielding layer 30, and details will not be repeated here. As for the structure of the first transfer layer 14, reference may be made to the above description, which will not be repeated here.

In S10, a third insulating layer 123 is formed, and the third insulating layer 123 covers the first transfer layer 14. The film structure of the third insulating layer 123 is shown in FIG. 12H. The third insulating layer 123 is provided therein with via holes for connection between functional layers.

In S11, an initial second active film layer is formed, and a second active film layer 16 is formed through a patterning process. The second active film layer 16 includes the active layer pattern T11 of the sensing transistor T1. The film layer structure of the second active film layer 16 is shown in FIG. 12I. As for the material of the second active film layer 16, reference may be made to the above description, and details will not be repeated here. As for the structure of the second active film layer 16, reference may be made to the above description, which will not be repeated here.

In S12, an initial first source-drain metal layer is formed, and a first source-drain metal layer 181 is formed through a patterning process. The film structure of the first source-drain metal layer 181 is shown in FIG. 12J. The first source-drain metal layer 181 includes first anode transfer patterns 1811, and may further include first voltage signal lines VDD, sensing line transfer patterns 1812 and first transfer patterns Se. As for the material of the first source-drain metal layer 181, reference may be made to the material of the light-shielding layer 30, and details will not be repeated here. The first anode transfer pattern 1811 of the first source-drain metal layer 181 and the active layer pattern T11 of the sensing transistor T1 directly overlap. As for the structure of the first source-drain metal layer 181, reference may be made to the above description, which will not be repeated here.

In S13, a sixth insulating layer 126 is formed, and the sixth insulating layer 126 covers the first source-drain metal layer 181. The film structure of the sixth insulating layer 126 is shown in FIG. 12K. The sixth insulating layer 126 is provided therein with via holes for connecting with the anode layer 21.

In S14, an initial second source-drain metal layer is formed, and a second source-drain metal layer 182 is formed through a patterning process. The film structure of the second source-drain metal layer 182 is shown in FIG. 12L. As for the material of the second source-drain metal layer 182, reference may be made to the material of the light-shielding layer 30, and details will not be repeated here. The second source-drain metal layer 182 includes sensing lines S and second anode transfer patterns 1851. As for the structure of the second source-drain metal layer 182, reference may be made to the above description, which will not be repeated here.

In some implementations, a second source-drain metal layer 182 including the sensing lines S and a fifth source-drain metal layer 185 including the second anode transfer patterns 1851 may be formed separately. Adjacent source-drain metal layers are separated by an insulating layer.

In S15, a planarization layer 19 is formed, and the planarization layer 19 covers the second source-drain metal layer 182. The film structure of the planarization layer 19 is shown in FIG. 12M. The planarization layer 19 is provided therein with via holes for connecting with the anode layer 21.

In S16, an initial anode layer is formed, and an anode layer 21 is formed through a patterning process. The film structure of the anode layer 21 is shown in FIG. 12N.

In S17, a pixel defining layer 22 is formed. As for the structure of the pixel defining layer 22, reference may be made to the above description, which will not be repeated here. The film structure of the pixel defining layer 22 is shown in FIG. 12O.

In some embodiments, patterns of at least two (e.g., two, or more) film layers in two adjacent sub-pixel regions arranged in the second direction Y are symmetrically arranged, and the symmetry axis is a straight line parallel to the first direction X.

For example, as shown in FIGS. 11A and 11B, the first pixel region P1 includes a first sub-pixel region SP11, a second sub-pixel region SP12, and a third sub-pixel region SP13. The fourth pixel region P4 includes a first sub-pixel region SP41, a second sub-pixel region SP42, and a third sub-pixel region SP43. In the second direction Y, the first sub-pixel region SP11 of the first pixel region P1 is adjacent to the first sub-pixel region SP41 of the fourth pixel region P4, the second sub-pixel region SP12 of the first pixel region P1 is adjacent to the second sub-pixel region SP42 of the fourth pixel region P4, and the third sub-pixel region SP13 of the first pixel region P1 is adjacent to the third sub-pixel region SP43 of the fourth pixel region P4.

In this way, film layer patterns in the first sub-pixel region SP11 of the first pixel region P1 and the first sub-pixel region SP41 of the fourth pixel region P4 are symmetrical about a straight line parallel to the first direction X. The second sub-pixel region SP12 of the first pixel region P1 and the second sub-pixel region SP42 of the fourth pixel region P4 are symmetrical about a straight line parallel to the first direction X. The third sub-pixel region SP13 of the first pixel region P1 and the third sub-pixel region SP43 of the fourth pixel region P4 are symmetrical about a straight line parallel to the first direction X. Due to the symmetrical arrangement along the second direction Y, it may be possible to reduce a total area of a plurality of sub-pixel regions, and in turn reduce a space occupied by a plurality of sub-pixels, which is conducive to improving the PPI of the display panel and simplifying the pattern design of each film layer.

The film layer structures located in the middle of adjacent sub-pixel regions in the second direction Y may overlap. For example, the first voltage signal line VDD may be shared by the first pixel region P1 and the fourth pixel region P4, the data signal transfer pattern may be shared by the first pixel region P1 and the fourth pixel region P4, and the sensing line may be shared by the first pixel region P1 and the fourth pixel region P4.

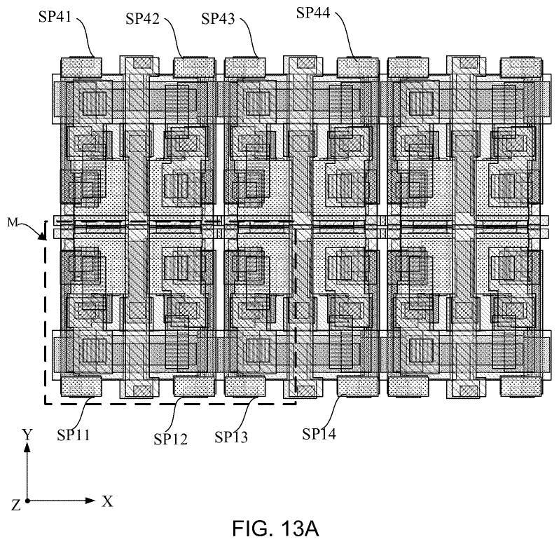

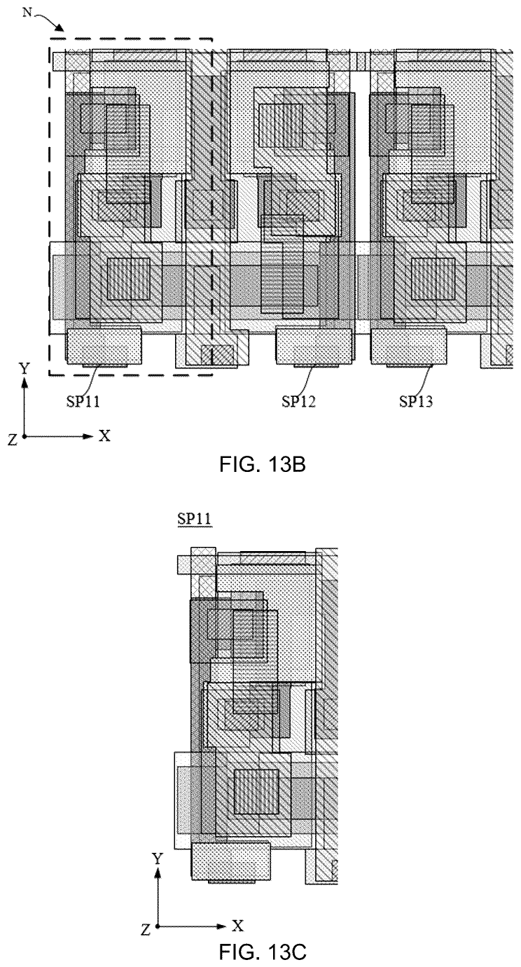

FIG. 13A is a structural diagram of stacked film layers in a plurality of sub-pixel regions of an array substrate according to some embodiments of the present disclosure. FIG. 13B is an enlarged view of the region M in FIG. 13A. FIG. 13C is an enlarged view of the region N in FIG. 13B.

As another example, as shown in FIG. 13A, the first pixel region P1 includes a first sub-pixel region SP11, a second sub-pixel region SP12, and a third sub-pixel region SP13.

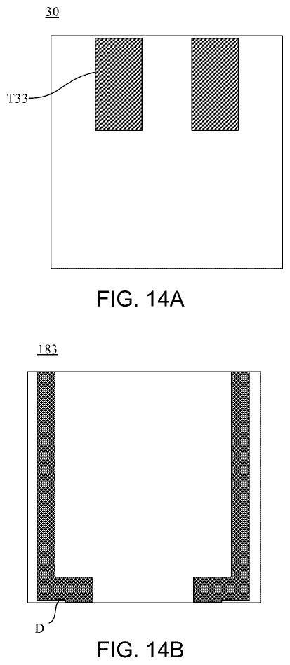

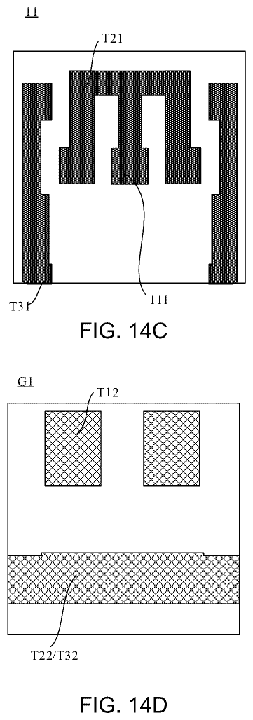

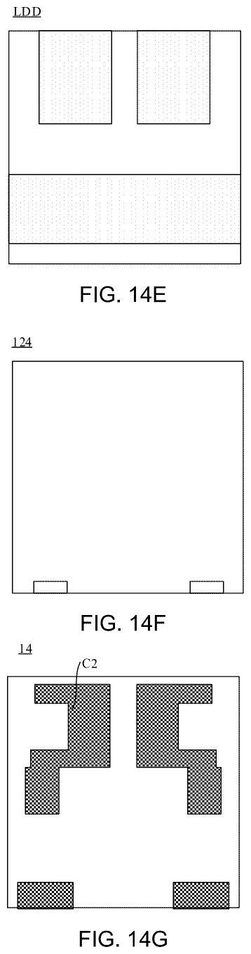

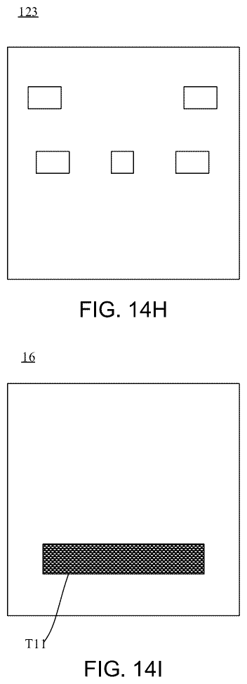

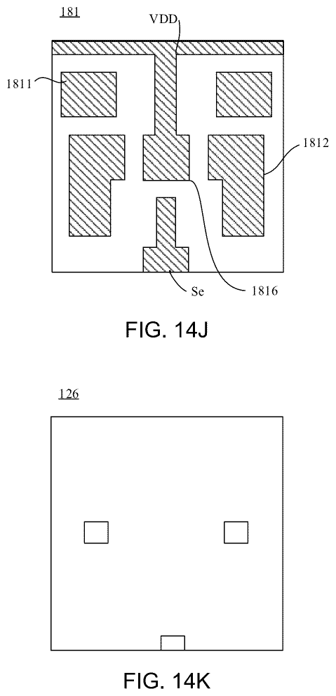

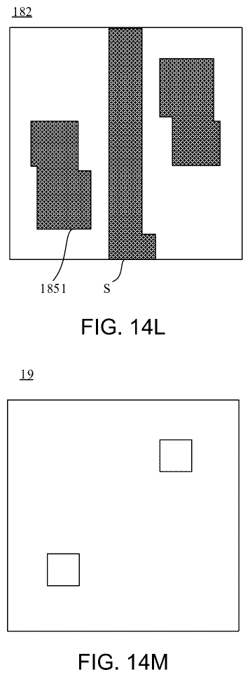

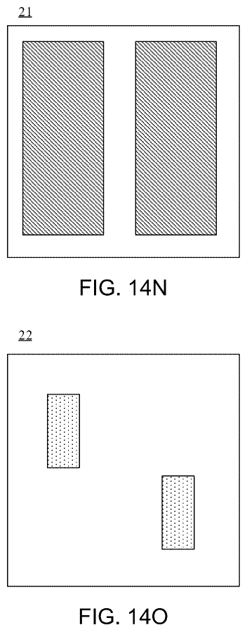

For example, as shown in FIGS. 14A to 14C, considering four adjacent sub-pixel regions in the first direction X as an example, the four sub-pixel regions include a first sub-pixel region SP11, a second sub-pixel region SP12, a third sub-pixel region SP13 and a fourth sub-pixel region SP14. In the first direction X, the first sub-pixel region SP11 is adjacent to the second sub-pixel region SP12, the second sub-pixel region SP12 is adjacent to the third sub-pixel region SP13, and the third sub-pixel region SP13 is adjacent to the fourth sub-pixel region SP14.

FIGS. 14A to 14O are structural diagrams of film layers, in accordance with some embodiments of the present disclosure.

FIGS. 14A to 14O are other structural diagrams of film layers in FIG. 7. Considering the first sub-pixel region SP11 and the second sub-pixel region SP12 as an example, steps of forming film layer patterns are as follows.

In S1, an initial light-shielding layer is formed on the base substrate 101 through deposition, and a light-shielding layer 30 is formed through a patterning process. Patterns of the light-shielding layer 30 in the first sub-pixel region SP11 and the second sub-pixel region SP12 are formed simultaneously. The film structure of the light-shielding layer 30 is shown in FIG. 14A. The patterns of the light-shielding layer 30 in the first sub-pixel region SP11 and the second sub-pixel region SP12 may be symmetrical and arranged in the first direction X. The light-shielding layer 30 may include a bottom-gate pattern T33 of a driving transistor T3. As for the material and structure of the light-shielding layer 30, reference is made to the above description, and details will not be repeated here.

In S2, the ninth insulating layer 129 is formed on the base substrate 101. The ninth insulating layer 129 covers the light-shielding layer 30. As for the material of the ninth insulating layer 129, reference may be made to the description of the above inorganic insulating material, which will not be repeated here.

In S3, an initial third source-drain metal layer is formed, and the third source-drain metal layer 183 is formed through a patterning process. The film structure of the third source-drain metal layer 183 is shown in FIG. 14B. The third source-drain metal layer 183 includes data signal lines D. The data signal lines D in the first sub-pixel region SP11 and the second sub-pixel region SP12 may be symmetrical and arranged in the first direction X. As for the material and structure of the third source-drain metal layer 183, reference is made to the above description, and details will not be repeated here.

In S4, the seventh insulating layer 127 is formed. The seventh insulating layer 127 covers the third source-drain metal layer 183.

In S5, an initial first active film layer is formed, and the first active film layer 11 is formed through a patterning process. The first active film layer 11 includes the active layer pattern T31 of the driving transistor T3 and the active layer pattern T21 of the writing transistor T2. The film structure of the first active film layer 11 is shown in FIG. 14C. The active layer patterns T21 of the writing transistors T2 in the first sub-pixel region SP11 and the second sub-pixel region SP12 are connected through a first connection pattern 111. As for the material and structure of the first active film layer 11, reference is made to the above description, and details will not be repeated here.

In S6, a fifth insulating layer 125 is formed, and the fifth insulating layer 125 covers the first active film layer 11.

In S7, an initial third gate film layer is formed, and a third gate film layer G3 is formed through a patterning process. The third gate film layer G3 includes the gate pattern T32 of the driving transistor T3, the gate pattern T12 of the sensing transistor T1, and the gate pattern T22 of the writing transistor T2. The film structure of the third gate film layer G3 is shown in FIG. 14D. As for the material and structure of the third gate film layer G3, reference is made to the above description, and details will not be repeated here.

There may also be a lightly doped drain (LDD) structure in the channel region of the transistor close to the drain. The film layer structure of the LDD is shown in FIG. 14E. The LDD structure is a low-doped drain region in the channel of the transistor close to the drain. The low-doped drain region is also subjected to some voltage. This structure may prevent the hot electron degradation effect.

In S8, a fourth insulating layer 124 is formed, and the fourth insulating layer 124 covers the third gate film layer G3. The film structure of the fourth insulating layer 124 is shown in FIG. 14F. The fourth insulating layer 124 is provided therein with via holes for connection between functional layers.

In S9, an initial first transfer layer is formed, and a first transfer layer 14 is formed through a patterning process. The first transfer layer 14 includes second electrode plates C2 of storage capacitors C. The film structure of the first transfer layer 14 is shown in FIG. 14G. As for the material and structure of the first transfer layer 14, reference is made to the above description, and details will not be repeated here. Patterns of the first transfer layer 14 in the first sub-pixel region SP11 and the second sub-pixel region SP12 may be symmetrical and arranged in the first direction X.

In S10, a third insulating layer 123 is formed, and the third insulating layer 123 covers the first transfer layer 14. The film structure of the third insulating layer 123 is shown in FIG. 14H. The third insulating layer 123 is provided therein with via holes for connection between functional layers.

In S11, an initial second active film layer is formed, and a second active film layer 16 is formed through a patterning process. The second active film layer 16 includes an active layer pattern T11 of the sensing transistor T1. The film layer structure of the second active film layer 16 is shown in FIG. 141. As for the material and structure of the second active film layer 16, reference is made to the above description, and details will not be repeated here.

In S12, an initial first source-drain metal layer is formed, and a first source-drain metal layer 181 is formed through a patterning process. The film structure of the first source-drain metal layer 181 is shown in FIG. 12J. The first source-drain metal layer 181 includes first anode transfer patterns 1811, and may further include first voltage signal lines VDD, sensing line transfer patterns 1812 and first transfer patterns Se. The first voltage signal lines VDD in the first sub-pixel region SP11 and the first voltage signal line VDD of the second sub-pixel region SP12 are connected through a second connection pattern 1816. As for the material and structure of the first source-drain metal layer 181, reference is made to the above description, and details will not be repeated here. The first anode transfer patterns 1811, the first voltage signal lines VDD, the sensing line transfer patterns 1812, and the first transfer patterns Se in the first sub-pixel region SP11 and the second sub-pixel region SP12 may be symmetrical and arranged in the first direction X.

In S13, a sixth insulating layer 126 is formed, and the sixth insulating layer 126 covers the first source-drain metal layer 181. The film structure of the sixth insulating layer 126 is shown in FIG. 14K. The sixth insulating layer 126 is provided therein with via holes for connecting with the anode layer 21.

In S14, an initial second source-drain metal layer is formed, and a second source-drain metal layer 182 is formed through a patterning process. The film structure of the second source-drain metal layer 182 is shown in FIG. 14L. The second source-drain metal layer 182 includes sensing lines S and second anode transfer patterns 1851. As for the material and structure of the second source-drain metal layer 182, reference is made to the above description, and details will not be repeated here.

In S15, a planarization layer 19 is formed, and the planarization layer 19 covers the second source-drain metal layer 182. The film structure of the planarization layer 19 is shown in FIG. 14M. The planarization layer 19 is provided therein with via holes for connecting with the anode layer 21.

In S16, an initial anode layer is formed, and an anode layer 21 is formed through a patterning process. The film structure of the anode layer 21 is shown in FIG. 14N. The anode layers 21 in the first sub-pixel region SP11 and the second sub-pixel region SP12 may be symmetrical and arranged in the first direction X.

In S17, a pixel defining layer 22 is formed. As for the structure of the pixel defining layer 22, reference may be made to the above description, which will not be repeated here. The film structure of the pixel defining layer 22 is shown in FIG. 14O.

In some embodiments, patterns of at least two (e.g., two, or more) film layers in every two adjacent sub-pixel regions arranged in the first direction X are symmetrically arranged, and the symmetry axis is a straight line parallel to the second direction Y. For example, the film layer patterns in the first sub-pixel region SP11 and the second sub-pixel region SP12 in the first direction X are symmetrical. The film layer structures of the light-shielding layer 30, the third source-drain metal layer 183, the first active film layer 11, the third gate film layer G1, the first transfer layer 14, the first active film layer 16, and the first source-drain metal layer 181 in the first sub-pixel region SP11 and the second sub-pixel region SP12 are symmetrical about a straight line parallel to the second direction Y. The via holes in the fourth insulating layer 124, the third insulating layer 123 and the sixth insulating layer 126 are also symmetrical about a straight line parallel to the second direction Y.

As another example, the film layer patterns in the second sub-pixel region SP12 and the third sub-pixel region SP13 are symmetrical about a straight line parallel to the second direction Y. As another example, the film layer patterns in the third sub-pixel region SP13 and the fourth sub-pixel region SP14 are symmetrical about a straight line parallel to the second direction Y.

The film layer structures in adjacent sub-pixel regions are symmetrical and arranged in the first direction X, which may reduce a total area of the plurality of sub-pixel regions and in turn reduce the space occupied by the plurality of sub-pixels, which is conducive to improving the PPI of the display panel and simplifying the pattern design of each film layer.

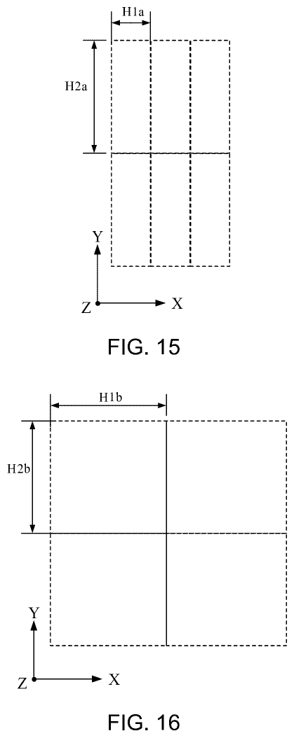

FIG. 15 is a structural diagram of a sub-pixel region according to some embodiments of the present disclosure. FIG. 16 is a structural diagram of another sub- pixel region according to some embodiments of the present disclosure.

In some embodiments, a size H2 of the sub-pixel region in the second direction Y is greater than a size H1 of the sub-pixel region in the first direction X, thereby reducing the size in the first direction X and in turn reducing the area of the pixel driving circuit in the first direction X.

For example, as shown in FIG. 15, a ratio of the size H1a of the sub-pixel region in the first direction X to the size H2a of the sub-pixel region in the second direction Y is 1:3. Three sub-pixel regions are arranged in the same row to constitute a pixel region. The size H2a of the three sub-pixel regions in the second direction Y is the same as a sum of the sizes Hla of the sub-pixel regions in the first direction X, so that the pixel region has the same size in the first direction X and the second direction Y.

As another example, as shown in FIG. 16, the ratio of the size H1b of the sub-pixel region in the first direction X to the size H2b of the sub-pixel region in the second direction Y is 1:2. Two sub-pixel regions are arranged in the same row, and two sub-pixel regions are arranged in the same column. In this way, two sub-pixel regions in the same row as a whole have the same size in the first direction X and the second direction Y. Therefore, the film layer pattern design of each pixel region is more compact, which increases the number of pixel driving circuits and improves the PPI of the display panel 100.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. An array substrate, comprising a plurality of pixel driving circuits arranged in a plurality of rows and a plurality of columns, each of the plurality of pixel driving circuits including a plurality of transistors, the plurality of transistors including at least a sensing transistor; wherein
the array substrate comprises:
a base substrate;
a transistor distribution layer disposed on a side of the base substrate, wherein the transistor distribution layer is provided therein with an active layer pattern of the sensing transistor and a gate pattern of the sensing transistor, and the active layer pattern of the sensing transistor is farther away from the base substrate than the gate pattern of the sensing transistor; and
a first source-drain metal layer disposed on a side of the transistor distribution layer away from the base substrate, wherein the first source-drain metal layer includes a first anode transfer pattern, and the first anode transfer pattern is connected to the active layer pattern of the sensing transistor.

2. The array substrate according to claim 1, wherein the active layer pattern of the sensing transistor is connected to a sensing line transfer pattern, and the sensing line transfer pattern is located in the first source-drain metal layer;
the array substrate further comprises:
a second source-drain metal layer including a sensing line, the active layer pattern of the sensing transistor being connected to the sensing line through the sensing line transfer pattern.

3. The array substrate according to claim 1, wherein the transistor distribution layer includes a plurality of transistor distribution sub-layers, and each of the transistor distribution sub-layers includes an active film layer and a gate film layer that are stacked; the active film layer includes an active layer pattern of a transistor, and the gate film layer includes a gate pattern of a transistor; active film layers of the plurality of transistor distribution sub-layers are stacked; an active film layer of at least one transistor distribution sub-layer is a polysilicon active film layer, and an active film layer of at least one transistor distribution sub-layer is an oxide active film layer;
the plurality of transistors further include a writing transistor and a driving transistor; at least one of active layer patterns of the sensing transistor, the writing transistor and the driving transistor is located in the polysilicon active film layer, and at least one of the active layer patterns is located in the oxide active film layer.

4. The array substrate according to claim 3, wherein the plurality of transistor distribution sub-layers include a first transistor distribution sub-layer and a second transistor distribution sub-layer; an active film layer of the first transistor distribution sub-layer is closer to the base substrate than an active film layer of the second transistor distribution sub-layer;
a gate film layer of the first transistor distribution sub-layer and a gate film layer of the second transistor distribution sub-layer are located between the active film layer of the first transistor distribution sub-layer and the active film layer of the second transistor distribution sub-layer; the gate film layer of the first transistor distribution sub-layer and the gate film layer of the second transistor distribution sub-layer are located in a same layer;
the writing transistor and the driving transistor are located in the first transistor distribution sub-layer, and the sensing transistor is located in the second transistor distribution sub-layer.

5. The array substrate according to claim 3, further comprising:
a third source-drain metal layer including a data signal line, wherein an active layer pattern of the writing transistor is connected to the data signal line through a data signal transfer pattern; the data signal transfer pattern is located in a first transfer gate film layer; the first transfer gate film layer is located between active film layers of adjacent transistor distribution sub-layers, or the first transfer gate film layer and the first source-drain metal layer are located in a same layer;
one of the second source-drain metal layer and the third source-drain metal layer is disposed on a side of the transistor distribution layer close to the base substrate, and another of the second source-drain metal layer and the third source-drain metal layer is disposed on a side of the first source-drain metal layer away from the base substrate.

6. The array substrate according to claim 5, wherein is the second source-drain metal layer is disposed on the side of the first source-drain metal layer away from the base substrate, and an orthogonal projection of the sensing line on the base substrate covers an orthogonal projection of a channel region of an active layer pattern of the sensing transistor on the base substrate.

7. The array substrate according to claim 3, wherein an active layer pattern of the writing transistor is connected to a gate pattern of the driving transistor through a first transfer pattern; and the first transfer pattern is located in the first source-drain metal layer.

8. The array substrate according to claim 3, wherein an active layer pattern of the driving transistor is connected to a first voltage signal line through via holes; and the first voltage signal line is located in the first source-drain metal layer.

9. The array substrate according to claim 3, further comprising:
a light-shielding layer disposed on a side of the transistor distribution layer close to the base substrate; wherein
at least one of the plurality of transistors is a dual-gate transistor, the dual-gate transistor is disposed in a transistor distribution sub-layer closest to the base substrate, and a gate film layer of the transistor distribution sub-layer closest to the base substrate includes a top-gate pattern of the dual-gate transistor; and
the light-shielding layer includes a bottom-gate pattern of the dual-gate transistor.

10. The array substrate according to claim 9, wherein the light-shielding layer and the second source-drain metal layer are located in a same layer.

11. The array substrate according to claim 1, wherein the array substrate comprises a plurality of sub-pixel regions arranged in a plurality of rows and a plurality of columns, and patterns of at least two film layers in every two adjacent sub-pixel regions arranged in a column direction are symmetrically arranged.

12. The array substrate according to claim 1, wherein the array substrate comprises a plurality of sub-pixel regions arranged in a plurality of rows and a plurality of columns, and patterns of at least two film layers in every two adjacent sub-pixel regions arranged in a row direction are symmetrically arranged.

13. The array substrate according to claim 11, wherein a size of a sub-pixel region in the column direction is greater than a size of the sub-pixel region in a row direction.

14. The array substrate according to claim 13, wherein a ratio of the size of the sub-pixel region in the row direction to the size of the sub-pixel region in the column direction is 1:3 or 1:2.

15. The array substrate according to claim 1, further comprising:
a planarization layer disposed on a side of the first source-drain metal layer away from the base substrate, wherein the first anode transfer pattern is connected to an anode through a via hole penetrating the planarization layer.

16. The array substrate according to claim 1, further comprising:
a planarization layer disposed on a side of the first source-drain metal layer away from the base substrate; and
a fifth source-drain metal layer disposed between the first source-drain metal layer and the planarization layer, wherein the fifth source-drain metal layer includes a second anode transfer pattern; and the first anode transfer pattern is connected to an anode through the second anode transfer pattern.

17. A display panel, comprising:
the array substrate according to of claim 1;
an anode layer disposed on a side of the array substrate, wherein the anode layer includes a plurality of anodes, and the plurality of anodes are connected to the array substrate.

18. A display apparatus, comprising the display panel according to claim 17.

19. The array substrate according to claim 2, wherein the transistor distribution layer includes a plurality of transistor distribution sub-layers, and each of the transistor distribution sub-layers includes an active film layer and a gate film layer that are stacked; the active film layer includes an active layer pattern of a transistor, and the gate film layer includes a gate pattern of a transistor; active film layers of the plurality of transistor distribution sub-layers are stacked; an active film layer of at least one transistor distribution sub-layer is a polysilicon active film layer, and an active film layer of at least one transistor distribution sub-layer is an oxide active film layer;
the plurality of transistors further include a writing transistor and a driving transistor; at least one of active layer patterns of the sensing transistor, the writing transistor and the driving transistor is located in the polysilicon active film layer, and at least one of the active layer patterns is located in the oxide active film layer.

20. The array substrate according to claim 12, wherein a size of a sub-pixel region in a column direction is greater than a size of the sub-pixel region in the row direction.
